(19) United States
(12) Patent Application Publication
(10) Pub. No.: US 2018/0248122 A1
(43) Pub. Date: Aug. 30, 2018

(54) INK COMPOSITION FOR ORGANIC SEMICONDUCTOR DEVICE AND ORGANIC SEMICONDUCTOR DEVICE INCLUDING THE SAME

(71) Applicant: DIC Corporation, Tokyo (JP)

(72) Inventors: Eiji Otsuki, Sakura-shi (JP); Yuusaku Gotou, Sakura-shi (JP)

(73) Assignee: DIC Corporation, Tokyo (JP)

(21) Appl. No.: 15/754,149

(22) PCT Filed: Aug. 18, 2016
(86) PCT No.: PCT/JP2016/074095

§ 371 Date: Feb. 21, 2018

(30) Foreign Application Priority Data
Aug. 24, 2015 (JP) 2015-164779

(51) Int. Cl. H01L 51/00; H01L 51/50

(52) U.S. Cl. CPC H01L 51/0043; H01L 51/0094; H01L 51/5056

(57) ABSTRACT

A leveling agent is oriented in the surface part of a layer formed from a coated film having the oriented leveling agent on its surface. The purpose of the present invention is to provide an ink composition for organic semiconductor device that can form a satisfactory film even on a low surface energy layer. The ink composition for organic semiconductor device contains a first organic semiconductor device material, a leveling agent, a first solvent, and an aromatic solvent. The leveling agent is a polymer at least containing a siloxane monomer as a monomer unit, and the first solvent has a surface tension of 25 mN/m or less.

### TECHNICAL FIELD

The present invention relates to an ink composition for organic semiconductor device and an organic semiconductor device including the composition.

### BACKGROUND ART

Organic semiconductor devices are electroluminescent devices including organic compounds (organic semiconductors) having semiconductor properties. Since the organic semiconductor devices include organic semiconductors, for example, a reduction in weight, an increase in area, and an increase in flexibility are possible. Therefore, recently, research and development in this field have been rapidly advanced. Incidentally, among the organic semiconductor devices, organic light-emitting devices, organic field-effect transistors, and organic solar cells are particularly attracting attention.

For example, an organic light-emitting device is focused as, for example, a next-generation flat panel display or next-generation lighting from the viewpoint such as excellent visibility, low viewing angle dependence, and a possibility of thinning.

The organic light-emitting device usually includes an anode, a hole transport layer, a light emitting layer, an electron transport layer, and a cathode. When a voltage is applied to the organic light-emitting device, holes are injected from the anode into the hole transport layer, and electrons are injected from the cathode into the electron transport layer. Subsequently, the holes and the electrons are injected into the light emitting layer. In the light emitting layer, the injected holes and electrons are recombined, and the energy generated at the time causes the light emitting material in the light emitting layer to emit light. In some cases, the organic light-emitting device does not include the hole transport layer and/or the electron transport layer. Alternately, the organic light-emitting device may include other layers such as a hole injection layer and an electron injection layer.

Recently, it has been attempted to produce the organic semiconductor device by a wet film-forming method that forms a film by applying an application liquid (ink composition) containing an organic material and drying the resulting coated film, instead of a dry film-forming method that forms a film by, for example, vapor deposition of an organic material, from the viewpoint such as an increase in the size and a reduction in cost.

As understood also from the light-emitting mechanism of the above-described organic light-emitting device in which holes and electrons move between layers, the current density highly depends on the film thickness, and a thin portion of a film causes a leakage current. Accordingly, the layers constituting an organic light-emitting device are required to be flat. Similarly, also in organic field-effect transistors and solar cells, the layers constituting them are required to be flat for preventing occurrence of leakage currents.

However, in formation of a layer constituting an organic semiconductor device by a wet film-forming method, it is difficult to ensure flatness, due to the method. As a method for achieving flatness of such a layer, for example, PTL 1 describes an invention according to an organic EL layer-forming coating liquid that is used in formation of an organic layer of an organic EL device. The organic EL layer-forming coating liquid is characterized in that the coating liquid contains a leveling agent and a light emitting material or a charge transport material and that the amount of the leveling agent (L) satisfies a relational expression: (viscosity (cp) of L)× (amount (wt %) of L with respect to the light emitting material or charge transfer material)<200. PTL 1 describes that the problems, such as uneven light emission, caused by uneven flatness of the film formed by the wet film-forming method can be solved by adding a specific amount of the leveling agent to the organic EL layer-forming coating liquid.

### CITATION LIST

### Patent Literature

PTL 1: Japanese Unexamined Patent Application Publication No. 2002-56980

### SUMMARY OF INVENTION

### Technical Problem

According to PTL 1, the layer formed by a wet film-forming method can have a certain flatness. More specifically, the leveling agent is oriented on the surface of a coated film formed by coating, resulting in prevention of occurrence of waviness to achieve flatness.

Herein, the leveling agent is oriented in the surface part of a layer formed from the coated film including the oriented leveling agent on its surface. It was revealed that in such a case, the surface of the layer has a small surface energy due to the presence of the leveling agent and as a result, in some cases, a wet film-forming method cannot or hardly form a layer on the layer including the leveling agent.

Accordingly, the purpose of the present invention is to provide an ink composition for organic semiconductor device that can form a satisfactory film even on a low surface energy layer.

### Solution to Problem

The present inventors diligently studied to solve the above-mentioned problems. As a result, the inventors found that the above-mentioned problems can be solved by an ink composition for organic semiconductor device containing a specific leveling agent and a specific solvent, and the present invention was accomplished.

That is, the present invention relates to an ink composition for organic semiconductor device including a first organic semiconductor device material, a leveling agent, a first solvent, and an aromatic solvent, wherein the leveling agent is a polymer at least containing a siloxane monomer as a monomer unit, and the first solvent has a surface tension of 25 mN/m or less.

### Advantageous Effects of Invention

According to the present invention, a film can be suitably formed even on a low surface energy layer.

### DESCRIPTION OF EMBODIMENTS

Embodiments of the present invention will now be described in detail.

<Ink Composition for Organic Semiconductor Device>

An ink composition for organic semiconductor device according to the embodiment includes a first organic semiconductor device material, a leveling agent, a first solvent, and an aromatic solvent. The leveling agent is a polymer at least containing a siloxane monomer as a monomer unit. The first solvent has a surface tension of 25 mN/m or less.

In a layer formed from an ink composition for organic semiconductor device containing a leveling agent, the leveling agent is oriented on the layer surface to reduce the surface energy. When a layer is further formed on such a low surface energy layer by a wet film-forming method using an ink composition for organic semiconductor device, a coated film is hardly formed or cannot be formed. Specifically, in application of an ink composition for organic semiconductor device, the contact angle is significantly large, and sufficient wettability cannot be ensured. For example, in the case in which the organic semiconductor device is an organic light-emitting device and a hole transport layer is formed on a hole injection layer as a low surface energy layer, when the hole transport layer is formed from an ink composition for organic light-emitting device as in PTL 1, sufficient wettability is not obtained. Accordingly, a coated film itself cannot be formed, and even if a coated film is formed, waviness occurs on the surface of the hole transport layer obtained by drying. As a result, the adhesion between the hole transport layer and a hole injection layer and/or between the hole transport layer and a light emitting layer (formed on the hole transport layer) is low, resulting in a reduction in the performance of the organic light-emitting device.

Alternatively, in order to achieve sufficient wettability, when a layer is formed from an ink composition for organic semiconductor device containing a solvent having a low surface energy, the organic semiconductor device material is hardly dissolved or cannot be dissolved in some cases, and the ink composition for organic semiconductor device has very narrow applicability or no applicability.

In contrast, the ink composition for organic semiconductor device according to the embodiment can suitably form a film even on a low surface energy layer.

Although the reasons for this are not necessarily clear, it is assumed to be due to the following mechanism: The ink composition for organic semiconductor device contains a first solvent having a surface tension of 25 mN/m or less, which improves the wettability of the ink composition for organic semiconductor device. Consequently, the ink composition can be suitably applied even onto a low surface energy layer. In addition, the ink composition for organic semiconductor device further contains an aromatic solvent having excellent solubility for the organic semiconductor device material and therefore can suitably dissolve the organic semiconductor device material. That is, both the wettability and the solubility of the organic semiconductor device material can be ensured by using both the first solvent and the aromatic solvent as the solvents.

Furthermore, since the leveling agent is a polymer at least containing a siloxane monomer as the monomer unit, a layer can be further certainly formed on a low surface energy layer. Specifically, the first solvent having a low surface energy is readily evaporated compared to the aromatic solvent. In this case, when a coated film formed from the ink composition for organic semiconductor device is dried, the first solvent can be preferentially evaporated from the coated film. If the drying process proceeds in such a circumstance, at the end of the process, the first solvent contributing to the wettability disappears or almost disappears from the coated film, resulting in a risk of causing waviness in the finally resulting layer. However, the leveling agent has a siloxane structure and is therefore readily oriented on the coated film surface, and the evaporation rates of the first solvent and the aromatic solvent can be suppressed. More specifically, the leveling agent oriented on the coated film surface can suppress or prevent the preferential evaporation of the first solvent. As a result, in the process of drying the coated film, the first solvent and the aromatic solvent are similarly evaporated, and the resulting layer can have excellent flatness. The mechanism of the action of the leveling agent is a conjecture, and even if the advantageous effects of the invention are obtained by a mechanism different from the above-described mechanism, the action is encompassed in the technical scope of the present invention.

An ink composition for organic light-emitting device will now be described in detail as an example of the ink composition for organic semiconductor device. Those skilled in the art can prepare an ink composition for organic field-effect transistor and an ink composition for organic solar cell using the materials used for the organic field-effect transistor and the organic solar cell by referring to the following description about the ink composition for organic light-emitting device and considering common technical knowledge at the time of filing. Those skilled in the art also can understand that the resulting ink composition for organic field-effect transistor and ink composition for organic solar cell also have the advantageous effects of the present invention.

[First Organic Light-Emitting Device Material (First Organic Semiconductor Device Material)]

When the organic semiconductor device is an organic light-emitting device, the first semiconductor device material is a first organic light-emitting device material.

The first organic light-emitting device material may be any material that constitutes an organic light-emitting device.

In one embodiment, the ink composition for organic light-emitting device can be applied onto a low surface energy layer formed by preferably a wet film-forming method. Examples of the low surface energy layer include a hole injection layer and a hole transport layer. Examples of the layer that can be formed on the hole injection layer includes a hole transport layer and a light emitting layer. Examples of the layer that can be formed on the hole transport layer include a light emitting layer. Accordingly, the first organic light-emitting device material is preferably a hole transport material used for the hole transport layer or a light emitting material used for the light emitting layer.

(Hole Transport Material)

The hole transport material has a function of efficiently transporting holes in the hole transport layer. Holes are generally transported from the hole transport material to the light emitting layer.

The hole transport material is not particularly limited, and examples thereof include low-molecular triphenylamine derivatives, such as TPD (N,N′-diphenyl-N,N′-di(3-methylphenyl)-1,1′-biphenyl-4,4′-diamine (the following chemical formula: HTM03)), α-NPD (4,4′-bis[N-(1-naphthyl)-N-phenylamino]biphenyl), and m-MTDATA (4,4′,4″-tris(3-methylphenylamino)triphenylamine); polyvinyl carbazole; and polymer compounds prepared by introducing substituents into the triphenylamine derivatives represented by the following chemical formula HTM01 or HTM02 (n: integer of 1 to 10000) and polymerizing each of the derivatives. Among these materials, the hole transport material is preferably a triphenylamine derivative or a polymer compound prepared by introducing a substituent into a triphenylamine derivative and polymerizing the derivative and more preferably HTM01, HTM02, or HTM03, from the viewpoint of excellent solubility in an aromatic solvent.

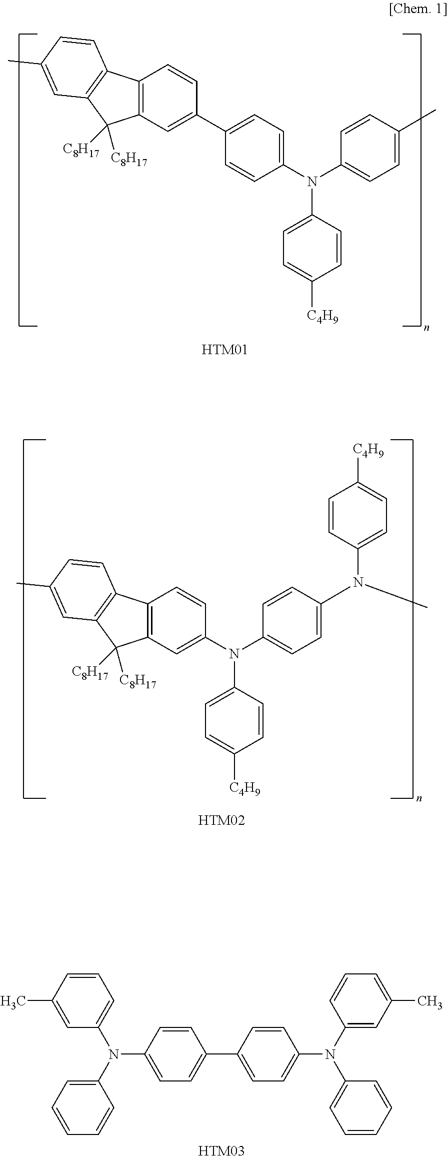

The above-described hole transport materials may be used alone or in combination of two or more thereof.

The content of the hole transport material is preferably 0.01 to 10 mass % and more preferably 0.01 to 5 mass % based on the total amount of the ink composition for organic light-emitting device. A hole transport material content of 0.01 mass % or more can efficiently transport holes and is therefore preferred. In addition, a hole transport material content of 10 mass % or less can prevent an increase in driving voltage and is therefore preferred.

(Light Emitting Material)

The light emitting material has a function of directly or indirectly contributing to light emission that uses holes and electrons in the light emitting layer. Throughout the specification, the term “light emission” encompasses light emission by fluorescence and light emission by phosphorescence.

In one embodiment, the light emitting material encompasses a host material and a dopant material.

Host Material

The host material generally has a function of transporting holes and electrons injected into the light emitting layer.

The host material may be any material having the above-mentioned function. The host material is classified into a high-molecular host material and a low-molecular host material. Throughout the specification, the term “low-molecular” means a weight-average molecular weight (Mw) of 5,000 or less, and the term “high-molecular” means a weight-average molecular weight (Mw) of higher than 5,000. On this occasion, in the specification, the value of “weight-average molecular weight (Mw)” is the value obtained by measurement with a high-performance gel permeation chromatography (GPC) apparatus (available from Tosoh Corporation) using polystyrene as a reference material.

The high-molecular host material is not particularly limited, and examples thereof include poly(9-vinylcarbazole) (PVK), polyfluorene (PF), polyphenylene vinylene (PPV), and copolymers containing monomer units thereof.

The high-molecular host material preferably has a weight-average molecular weight (Mw) of higher than 5,000 and 5,000,000 or less and more preferably higher than 5,000 and 1,000,000 or less.

The low-molecular host material is not particularly limited, and examples thereof include 4,4′-bis(9H-carbazol-9-yl)biphenyl (CBP), bis(2-methyl-8-quinolinolato)-4-(phenylphenolato)aluminum (BAlq), 1,3-dicarbazolylbenzene (mCP), 4,4′-bis(9-carbazolyl)-2,2′-dimethylbiphenyl (CDBP), N,N′-dicarbazolyl-1,4-dimethylbenzene (DCB), 2,7-bis(diphenylphosphine oxide)-9,9-dimethyifluorescein (P06), 3,5-bis(9-carbazolyl)tetraphenylsilane (SimCP), 1,3-bis(triphenylsilyl)benzene (UGH3), 1,3,5-tris[4-(diphenylamino)phenyl]benzene (TDAPB), 9,9′-(p-tert-butylphenyl)-1,3-biscarbazole (TBPBCz), 3-(biphenyl-4-yl)-5-(4-tert-butylphenyl)-4-phenyl-4H-1,2,4-triazole (TAZ), 3-(4-(9H-carbazol-9-yl)phenyl)-9-(4,6-diphenyl-1,3,5-triazin-2-yl)-9H-carbazole (CPCBPTz), and 9-(4,6-diphenyl-1,3,5-triazin-2-yl)-9′-phenyl-3,3′-biscarbazole (CzT).

The low-molecular host material preferably has a weight-average molecular weight (Mw) of 100 to 5,000 and more preferably 300 to 5,000.

Among the above-mentioned host materials, the host material is preferably a low-molecular host material, more preferably 4,4′-bis(9H-carbazol-9-yl)biphenyl (CBP), bis(2-methyl-8-quinolinolato)-4-(phenylphenolato)aluminum (BAlq), 9,9′-(p-tert-butylphenyl)-1,3-biscarbazole (TBPBCz), or 9-(4,6-diphenyl-1,3,5-triazin-2-yl)-9′-phenyl-3,3′-biscarbazole (CzT), and further preferably 4,4′-bis(9H-carbazol-9-yl)biphenyl (CBP), 9,9′-(p-tert-butylphenyl)-1,3-biscarbazole (TBPBCz), or 9-(4,6-diphenyl-1,3,5-triazin-2-yl)-9′-phenyl-3,3′-biscarbazole (CzT).

The above-mentioned host materials may be used alone or in combination of two or more thereof.

The content of the host material is preferably 0.1 to 10 mass % and more preferably 0.1 to 5 mass % based on the total amount of the ink composition for organic light-emitting device. A host material content of 0.1 mass % or more can shorten the distance between a host molecule and a dopant molecule and is therefore preferred. A host material content of 10 mass % or less can prevent a reduction in quantum yield and is therefore preferred.

Dopant Material

The dopant material has a function of emitting light by using energy generated by recombination of the transported holes and electrons.

The dopant material may be any material having the above-mentioned function. The dopant material is generally classified into a high-molecular dopant material and a low-molecular dopant material.

The high-molecular dopant material is not particularly limited, and examples thereof include polyphenylene vinylene (PPV), cyanopolyphenylene vinylene (CN-PPV), poly(fluorenylene ethylene) (PFE), polyfluorene (PFO), polythiophene polymer, polypyridine, and copolymers containing monomer units thereof.

The high-molecular dopant material preferably has a weight-average molecular weight (Mw) of higher than 5,000 and 5,000,000 or less and more preferably higher than 5,000 and 1,000,000 or less.

The low-molecular dopant material is not particularly limited, and examples thereof include a fluorescence emitting material and a phosphorescence emitting material.

Examples of the fluorescence emitting material include naphthalene; perylene; pyrene; chrysene; anthracene; coumarin; p-bis(2-phenylethenyl)benzene; quinacridone; coumarin; aluminum complexes, such as Al(C₉H₆NO)₃; rubrene; perimidone; dicyanomethylene-2-methyl-6-(p-dimethylaminostyryl)-4H-pyran (DCM); benzopyran; rhodamine; benzothioxanthene; azabenzothioxanthene; triphenylamine; and derivatives thereof.

Examples of the phosphorescence emitting material include a complex containing a central metal of groups 7 to 11 of the periodic table and an aromatic ligand coordinated to the central metal.

Examples of the central metal of groups 7 to 11 of the periodic table include ruthenium, rhodium, palladium, osmium, iridium, gold, platinum, silver, and copper. Among these metals, the central metal is preferably iridium or platinum.

Examples of the ligand include phenylpyridine, diphenylpyridine, p-tolylpyridine, thienylpyridine, difluorophenylpyridine, phenylisoquinoline, fluorenopyridine, fluorenoquinoline, acetylacetone, and derivatives thereof. Among these ligands, preferred ligands are phenylpyridine, diphenylpyridine, p-tolylpyridine, and derivatives thereof, and more preferred are p-tolylpyridine and derivatives thereof.

More specifically, examples of the phosphorescence emitting material include tris(2-phenylpyridine)iridium (Ir(ppy)₃), tris(2-phenylpyridine) ruthenium, tris(2-phenylpyridine)palladium, bis(2-phenylpyridine)platinum, tris(2-phenylpyridine)osmium, tris(2-phenylpyridine)rhenium, tris[2-(p-tolyl)pyridine]iridium (Ir(mppy)₃), tris[2-(p-tolyl)pyridine]ruthenium, tris[2-(p-tolyl)pyridine]palladium, tris[2-(p-tolyl)pyridine]platinum, tris[2-(p-tolyl)pyridine]osmium, tris[2-(p-tolyl)pyridine]rhenium, octaethyl platinum porphyrin, octaphenyl platinum porphyrin, octaethyl palladium porphyrin, and octaphenyl palladium porphyrin.

Among the above-mentioned examples, the dopant material is preferably a low-molecular dopant material, more preferably a phosphorescence emitting material, and further preferably tris[2-(p-tolyl)pyridine]iridium (Ir(mppy)₃).

The low-molecular dopant material preferably has a weight-average molecular weight (Mw) of 100 to 5,000 and more preferably 100 to 3,000.

The above-mentioned dopant materials may be used alone or in combination of two or more thereof.

The content of the dopant material is preferably 0.01 to 10 mass % and more preferably 0.01 to 5 mass % based on the total amount of the ink composition for organic light-emitting device. A dopant material content of 0.01 mass % or more can enhance the emission intensity and is therefore preferred. A dopant material content of 10 mass % or less can prevent a reduction in quantum yield and is therefore preferred.

Among the above-mentioned examples, the light emitting material is preferably a low-molecular light emitting material, more preferably a combination of a low-molecular host material and a low-molecular dopant material, and further preferably a combination of tris[2-(p-tolyl)pyridine]iridium (Ir(mppy)₃) and 9,9′-(p-tert-butylphenyl)-1,3-biscarbazole, from the viewpoint of achieving higher light emission efficiency.

[Leveling Agent]

The leveling agent has a function of suppressing or preventing the preferential evaporation of the first solvent during drying of a coated film formed from the ink composition for organic light-emitting device by being oriented on the surface of the coated film.

The leveling agent also has a function of suppressing or preventing occurrence of waviness in a layer by being oriented on the surface of a coated film formed from the ink composition for organic light-emitting device.

The leveling agent according to the embodiment is a polymer at least containing a siloxane monomer as a monomer unit. The leveling agent may further contain an aromatic group-containing monomer as a monomer unit. The leveling agent may contain a hydrophobic monomer as a monomer unit and may further contain, for example, a component caused by a polymerization initiator.

(Siloxane Monomer)

The siloxane monomer includes a siloxane group, a polymerizable functional group, and a first linking group. The first linking group bonds between the siloxane group and the polymerizable functional group. Throughout the specification, the term “siloxane” refers to the structure “—Si—O—Si—” (siloxane structure).

The siloxane group of the siloxane monomer is not particularly limited and is preferably a siloxane group represented by Formula (1).

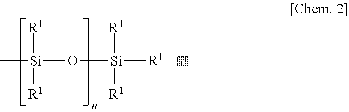

In Formula (1), R¹s each independently represent, for example, a hydrogen atom, a C1-C30 alkyl group, a C3-C30 cycloalkyl group, or a C1-C30 alkylsilyloxy group.

Examples of the C1-C30 alkyl group include, but not limited to, methyl, ethyl, propyl, isopropyl, butyl, iso-butyl, sec-butyl, tert-butyl, pentyl, hexyl, decyl, undecyl, and octadecyl.

Examples of the C3-C30 cycloalkyl group include, but not limited to, cyclopropyl, cyclobutyl, cyclopentyl, cyclohexyl, cycloheptyl, tricyclo[5,2,1,0(2,6)]decyl, and adamatyl.

Examples of the C1-C30 alkylsilyloxy group include, but not limited to, methylsilyloxy, dimethylsilyloxy, trimethylsilyloxy, ethylsilyloxy, diethylsilyloxy, triethylsilyloxy, ethylmethylsilyloxy, and diethylmethylsilyloxy.

In these groups, at least one of the hydrogen atoms constituting the C1-C30 alkyl group, the C3-C30 cycloalkyl group, or the C1-C30 alkylsilyloxy group may be substituted with a substituent. Examples of the substituent include a halogen atom; a hydroxy group; a thiol group; a nitro group; a sulfo group; C1-C10 alkoxy groups, such as methoxy, ethoxy, propyl, isopropyloxy, and butoxy; C1-C10 alkylamino groups, such as methylamino, ethylamino, dimethylamino, and diethylamino; C2-C10 alkylcarbonyl groups, such as methylcarbonyl, ethylcarbonyl, propylcarbonyl, and butylcarbonyl; and C2-C10 alkyloxycarbonyl groups, such as methyloxycarbonyl, ethyloxycarbonyl, propyloxycarbonyl, and butyloxycarbonyl.

Among these substituents, R¹ preferably includes a hydrogen atom, a C1-C30 alkyl group, or a C1-C30 alkylsilyloxy group, more preferably a hydrogen atom, methyl, ethyl, propyl, isopropyl, butyl, iso-butyl, sec-butyl, tert-butyl, trimethylsilyloxy, or triethylsilyloxy, and further preferably a hydrogen atom, methyl, ethyl, propyl, or trimethylsilyloxy.

n is 1 to 1000 and preferably 1 to 200.

The polymerizable functional group of the siloxane monomer is not particularly limited, and examples thereof include acryl, methacryl, glycidyl, vinyl, and vinylidene. Among these groups, the polymerizable functional group is preferably acryl or methacryl.

Examples of the first linking group of the siloxane monomer include a single bond, an oxygen atom, a sulfur atom, and a C1-C10 alkylene group.

The C1-C10 alkylene group is not particularly limited, and examples thereof include methylene, ethylene, propylene, isopropylene, butylene, iso-butylene, sec-butylene, and pentylene.

Herein, at least one of the hydrogen atoms constituting the C1-C10 alkylene group may be substituted with the above-mentioned substituents.

Among the above-mentioned examples, the first linking group is preferably a single bond or a C1-C10 alkylene group and more preferably a single bond, methylene, ethylene, or propylene.

Examples of the siloxane monomer are specifically shown below.

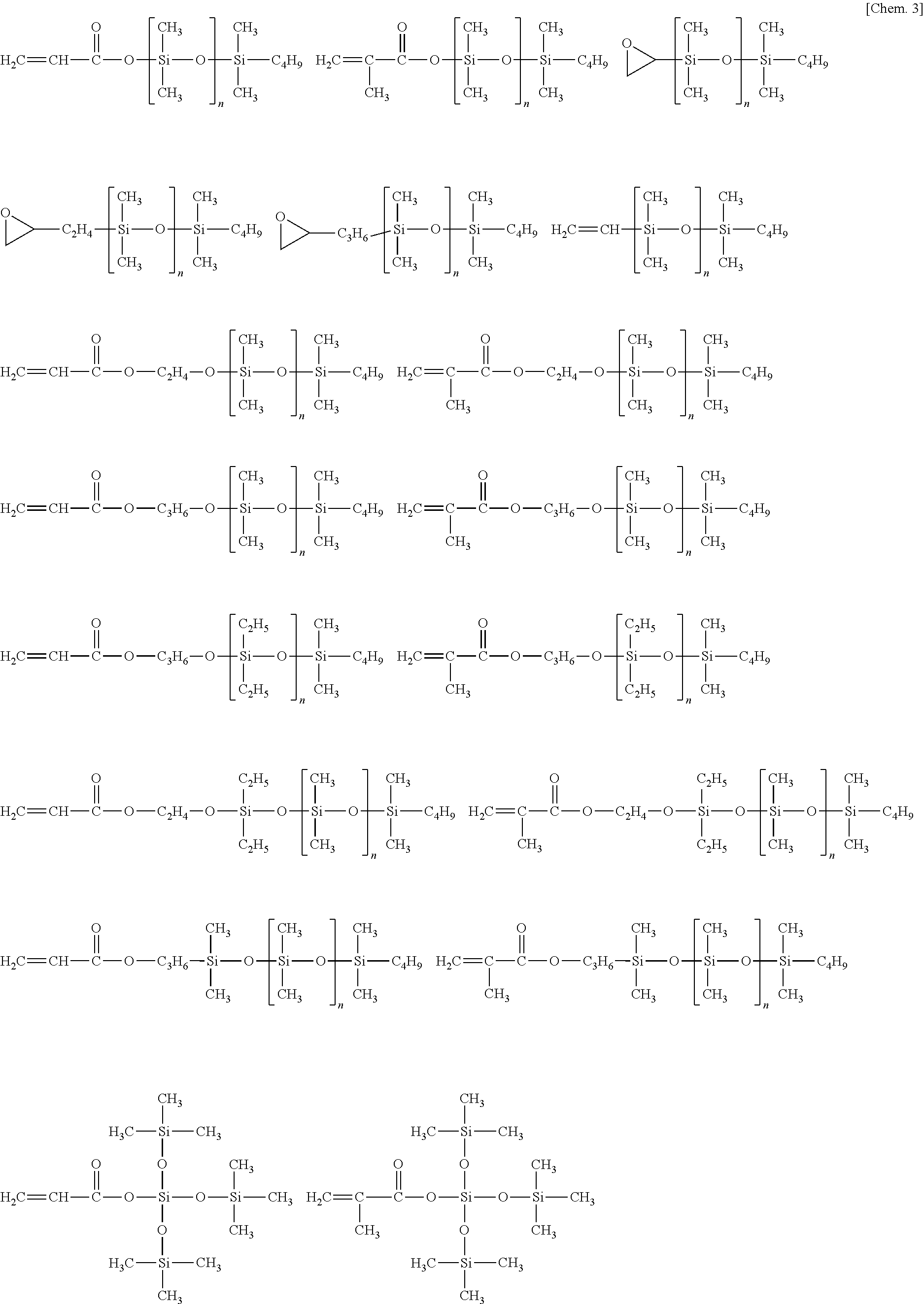

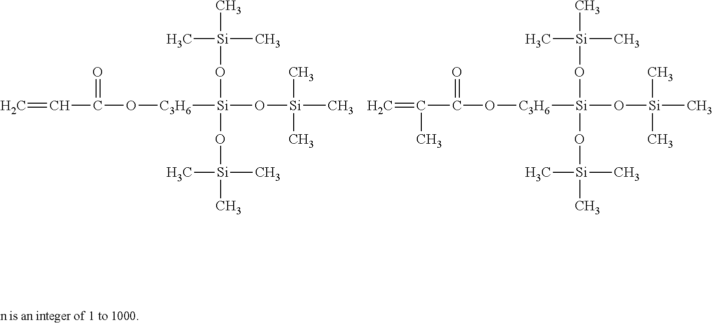

The above-mentioned siloxane monomers may be used alone or in combination of two or more thereof.

(Aromatic Group-Containing Monomer)

The aromatic group-containing monomer has a function of increasing the affinity with an aromatic solvent. Consequently, the leveling agent can be suitably dissolved. As a result, the ink composition for organic light-emitting device can be easily applied, and the resulting coated film can have flatness.

The aromatic group-containing monomer includes an aromatic group, a polymerizable functional group, and a second linking group. The second linking group bonds between the aromatic group and the polymerizable functional group.

Although the aromatic group is not particularly limited, it is a C6-C30 aryl group. Examples of the C6-C30 aryl group include phenyl, naphthyl, anthracenyl, and biphenyl. Herein, at least one of the hydrogen atoms constituting the C6-C30 aryl group may be substituted with a C1-C30 alkyl group, a C3-C30 cycloalkyl group, or the above-mentioned substituents.

The polymerizable functional group of the aromatic group-containing monomer is not particularly limited, and examples thereof include acryl, methacryl, glycidyl, and vinyl. Among these groups, the polymerizable functional group is preferably acryl or vinyl.

Examples of the second linking group of the aromatic group-containing monomer include a single bond, an oxygen atom, a sulfur atom, and a C1-C10 alkylene group.

Specifically, examples of the aromatic group-containing monomer include aryl methacrylates, such as phenyl methacrylate, naphthyl methacrylate, biphenyl methacrylate, benzyl methacrylate, and 2-ethylphenyl methacrylate; aryl acrylates, such as phenyl acrylate, naphthyl acrylate, biphenyl acrylate, benzyl acrylate, and 2-ethylphenyl acrylate; aryl glycidyl ethers, such as glycidyl phenyl ether; aryl vinyl, such as styrene, vinyltoluene, 4-vinylbiphenyl, and 2-vinylnaphthalene; aryl phenyl ethers, such as phenyl vinyl ether; and aryl vinylidene, such as 1,1-diphenylethylene.

Among these monomers, from the viewpoint of high affinity with an aromatic solvent, aryl vinyl and aryl vinylidene are preferred, and styrene and 1,1-diphenylethylene are more preferred.

The aromatic group-containing monomers may be used alone or in combination of two or more thereof.

(Hydrophobic Monomer)

The hydrophobic monomer has a function of adjusting the performance of the leveling agent.

The hydrophobic monomer includes a hydrophobic group, a polymerizable functional group, and a third linking group. The third linking group bonds between the hydrophobic group and the polymerizable functional group. The hydrophobic monomer does not contain an aromatic group and therefore does not correspond to the aromatic group-containing monomer. Throughout the specification, the term “hydrophobic group” means that the solubility (25° C., 25% RH) of a molecule composed of the hydrophobic group and a hydrogen atom bonded to each other in water is 100 mg/L or less.

The hydrophobic group is not particularly limited, and examples thereof include a C1-C30 alkyl group and a C3-C30 cycloalkyl group.

The C1-C30 alkyl group and the C3-C30 cycloalkyl group are the same as those described above.

Herein, at least one of the hydrogen atoms constituting the C1-C10 alkyl group or the C3-C30 cycloalkyl group may be substituted with the above-mentioned substituents within a range showing hydrophobicity.

The polymerizable functional group of the hydrophobic monomer is not particularly limited, and examples thereof include acryl, methacryl, glycidyl, and vinyl. Among these groups, the polymerizable functional group is preferably acryl or methacryl.

Examples of the third linking group of the hydrophobic monomer include a single bond, an oxygen atom, and a sulfur atom.

Specifically, examples of the hydrophobic monomer include alkyl methacrylates, such as methyl methacrylate, ethyl methacrylate, propyl methacrylate, isopropyl methacrylate, butyl methacrylate, 2-ethylhexyl methacrylate, stearyl methacrylate, and 2-(dimethylamino)ethyl methacrylate; alkyl acrylates, such as methyl acrylate, ethyl acrylate, propyl acrylate, isopropyl acrylate, butyl acrylate, 2-ethylhexyl acrylate, stearyl acrylate, and 2-(dimethylamino)ethyl acrylate; alkyl glycidyl ethers, such as methyl glycidyl ether, ethyl glycidyl ether, and butyl glycidyl ether; alkyl vinyl ethers, such as methyl vinyl ether and ethyl vinyl ether; cycloalkyl methacrylates, such as cyclopentyl methacrylate and cyclohexyl methacrylate; cycloalkyl acrylates, such as cyclopentyl acrylate and cyclohexyl acrylate; cycloalkyl glycidyl ethers, such as cyclohexyl glycidyl ether; and cycloalkyl vinyl ethers, such as cyclohexyl vinyl ether.

The hydrophobic monomers may be used alone or in combination of two or more thereof.

(Polymerization Initiator)

The polymerization initiator generally has a function as an initiator for a polymerization reaction that is applied for forming a polymer. The polymerization initiator can initiate polymerization by reacting with, for example, the polymerizable functional group of a siloxane monomer, the polymerizable functional group of an aromatic group-containing monomer, or the polymerizable functional group of a hydrophobic monomer. In such a case, the resulting polymer may contain a component derived from the polymerization initiator.

The polymerization initiator is not particularly limited, and examples thereof include a radical polymerization initiator and an ionic polymerization initiator.

Examples of the radical polymerization initiator include organic peroxides, such as di-t-butyl peroxide, t-butyl hydroperoxide, t-butyl peroxybenzoate, cumene hydroperoxide, isobutyl peroxide, lauroyl peroxide, 3,5,5-trimethylhexanoyl peroxide, t-butyl peroxypivalate, benzoyl peroxide, and methyl ethyl ketone peroxide; and azo compounds, such as 2,2′-azobisisobutyronitrile (AIBN), 1,1′-azobis(cyclohexanecarbonitrile) (ABCN), 2,2′-azobis-2-methylbutyronitrile (AMBN), 2,2′-azobis-2,4-dimethylvaleronitrile (ADVN), and 4,4′-azobis-4-cyanovaleric acid (ACVA). Among these initiators, the radical polymerization initiator is preferably an azo compound and more preferably 2,2′-azobisisobutyronitrile (AIBN). These radical polymerization initiators may be used alone or in combination of two or more thereof.

Examples of the ionic polymerization initiator include a cationic polymerization initiator and an anionic polymerization initiator.

Examples of the cationic polymerization initiator include sulfonium salts, such as triphenylsulfonium tetrafluoroborate, triphenylsulfonium hexafluorophosphate, and triphenylsulfonium hexafluoroantimonate; bissulfonyldiazomethanes, such as bis(p-toluenesulfonyl)diazomethane and bis(1,1-dimethylethylsulfonyl)diazomethane; nitrobenzyl derivatives, such as 2-nitrobenzyl p-toluenesulfonate and 2,6-dinitrobenzyl p-toluenesulfonate; sulfonic acid esters, such as pyrogallol trimesylate, pyrogallol tritosylate, benzyl tosylate, and benzyl sulfonate; and benzoin tosylates, such as benzoin tosylate.

Examples of the anionic polymerization initiator include an organic lithium compound. The organic lithium compound is not particularly limited, and examples thereof include alkyl lithiums, such as methyl lithium, ethyl lithium, propyl lithium, butyl lithium, sec-butyl lithium, iso-butyl lithium, tert-butyl lithium, pentyl lithium, and hexyl lithium; alkoxy alkyl lithiums, such as methoxy methyl lithium and ethoxy methyl lithium; alkenyl lithiums, such as vinyl lithium, allyl lithium, propenyl lithium, and butenyl lithium; alkynyl lithiums, such as ethynyl lithium, butynyl lithium, pentynyl lithium, and hexynyl lithium; aralkyl lithiums, such as benzyl lithium, phenylethyl lithium, and α-methylstyryl lithium; aryl lithiums, such as phenyl lithium and naphthyl lithium; diaryl alkyl lithiums, such as 1,1-diphenylethylene lithium, 1,1-diphenylhexyl lithium, 1,1-diphenyl-3-methylpentryl lithium, and 3-methyl-1,1-diphenylpentyl lithium; heterocyclic lithiums, such as 2-thienyl lithium, 4-pyridyl lithium, and 2-quinolyl lithium; and alkyl lithium magnesium complexes, such as tri(n-butyl)magnesium lithium and trimethyl magnesium lithium.

The above-mentioned ionic polymerization initiators may be used alone or in combination of two or more thereof.

Among the above-mentioned polymerization initiators, although it differs depending on the form of the leveling agent, preferred are the radical polymerization initiator and the anionic polymerization initiator; more preferred is the radical polymerization initiator; further preferred are benzoyl peroxide, t-butyl peroxybenzoate, and 2,2′-azobisisobutyronitrile (AIBN); and particularly preferred are benzoyl peroxide and t-butyl peroxybenzoate.

(Leveling Agent)

The leveling agent according to the embodiment is a polymer at least containing a siloxane monomer as a monomer unit. The polymer may be a homopolymer or may be a copolymer. Herein, the copolymer may be a random copolymer, an alternating polymer, a graft copolymer, or a block copolymer. Among these copolymers, the leveling agent is preferably a copolymer, more preferably a random polymer or a block copolymer, and further preferably a block copolymer. When the leveling agent is a block copolymer, the function of the leveling agent, specifically, the effects of suppressing or preventing preferential evaporation of the first solvent and/or suppressing or preventing occurrence of waviness in a layer can be suitably achieved. More specifically, when the leveling agent is a block copolymer, the siloxane structure is partially unevenly distributed compared to the case of using a random copolymer, and the function of the leveling agent can be suitably shown. An even distribution of the siloxane structure constituting the leveling agent and the structure derived from the aromatic group-containing monomer and/or the structure derived from the hydrophobic monomer enhances the tendency of orientation of the siloxane structure on the surface of a coated film and of orientation of the structure derived from the aromatic group-containing monomer and/or the structure derived from the hydrophobic monomer in the inside the coated film. Accordingly, the function of the leveling agent can be more suitably shown.

The structure of the leveling agent can be determined based on its production method. On this occasion, the production method is not particularly limited, and any known technique can be appropriately employed. In the production of the leveling agent, the structure and performance of the resulting leveling agent can be controlled by changing the amount of the monomer and the production conditions (e.g., temperature and pressure).

The specific structure of the leveling agent can be controlled by the production method as described above, and in one embodiment, examples of the structure include a homopolymer of a siloxane monomer represented by any of the following formulae (1-1) to (1-4) and a copolymer containing two or more siloxane monomers represented by formulae (1-1) to (1-4).

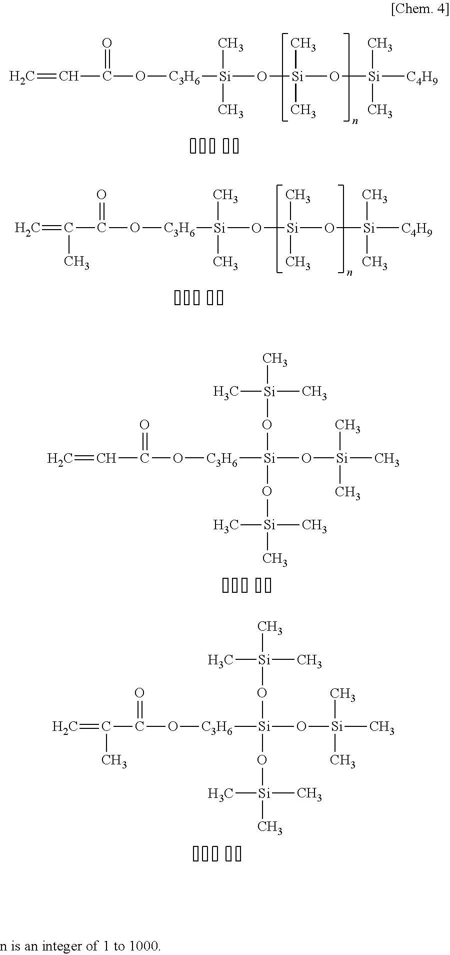

In another embodiment, examples of the specific structure of the leveling agent include a random polymer composed of at least one of the siloxane monomers (1-1) to (1-4) and at least one aromatic group-containing monomer selected from styrene, 4-vinylbiphenyl, and 2-vinylnaphthalene.

In further another embodiment, examples of the specific structure of the leveling agent include a block copolymer composed of at least one of the siloxane monomers (1-1) to (1-4) and at least one aromatic group-containing monomer selected from styrene, 4-vinylbiphenyl, and 2-vinylnaphthalene.

The above-mentioned leveling agents may be used alone or in combination of two or more thereof. For example, a mixture of a random copolymer and a block copolymer can be used.

The silicon content of the leveling agent is preferably 10 mass % or more, more preferably 18 mass % or more, and further preferably 20 to 25 mass %. When the silicon content of the leveling agent is 10 mass % or more, the ability of surface adjustment is increased, and the function (the effect of suppressing or preventing preferential evaporation of the first solvent and/or the effect of suppressing or preventing occurrence of waviness in a layer) of the leveling agent can be effectively shown, and such a content is therefore preferred. The silicon content of the leveling agent can be controlled by appropriately controlling the amount of the siloxane monomer. In this specification, the value of “silicon content rate” is that calculated by the following expression.

$$[ Math . 1 ]$$

$$Silicon content ( mass \% ) = \frac{\begin{matrix}Atomic weight of silicon \times \\ The number of silicon atoms per molecule\end{matrix}}{Leveling agent molecular weight} \times 100$$

The leveling agent preferably has a weight-average molecular weight (Mw) of 500 to 100,000 and more preferably 3,000 to 40,000. A leveling agent having a weight-average molecular weight (Mw) within the above-mentioned range can effectively show the function of the leveling agent and is therefore preferred.

The non-volatile content of the leveling agent is preferably 0.001 to 5.0 mass % and more preferably 0.001 to 1.0 mass % when the total amount of the first organic light-emitting device material, the leveling agent, the first solvent, and the aromatic solvent is defined as 100 mass %. When the non-volatile content of the leveling agent is 0.001 mass % or more, the function of the leveling agent can be suitably shown, and such a content is therefore preferred. In contrast, when the non-volatile content of the leveling agent is 5.0 mass % or less, the light emission efficiency is stabilized, and such a content is therefore preferred.

(Method of Producing Leveling Agent)

The leveling agent is produced by a known method without particular limitation.

For example, when the leveling agent is a block copolymer, the production method is, for example, living anionic polymerization.

Specifically, the living anionic polymerization is, for example, (1) a method involving preparation of polysiloxane through anionic polymerization of a siloxane monomer using a polymerization initiator and then anionic polymerization of the polysiloxane with, for example, an aromatic group-containing monomer or (2) a method involving preparation of, for example, an aromatic group-containing polymer through anionic polymerization of an aromatic group-containing monomer using a polymerization initiator and then anionic polymerization of the hydrophobic polymer with a siloxane monomer.

Although the amount of the polymerization initiator differs depending on the structure of the desired leveling agent, the amount is preferably 0.001 to 1 parts by mass, more preferably 0.005 to 0.5 parts by mass, and further preferably 0.01 to 0.3 parts by mass based on 100 parts by mass of the monomer.

The polymerization reaction may be carried out in the absence of a solvent or may be carried out in a solvent. When the polymerization is carried out in a solvent, the usable solvent is not particularly limited, and examples thereof include aliphatic hydrocarbon solvents, such as pentane, hexane, heptane, and octane; alicyclic hydrocarbon solvents, such as cyclopentane, methylcyclopentane, cyclohexane, and methylcyclohexane; aromatic hydrocarbon solvents, such as benzene, xylene, toluene, and ethylbenzene; and polar aprotic solvents, such as tetrahydrofuran, dimethyl formamide, and dimethyl sulfoxide. These solvents may be used alone or in combination of two or more thereof.

Although the amount of the solvent used in the polymerization reaction is not particularly limited, the amount is preferably 0 to 2000 parts by mass, more preferably 10 to 1000 parts by mass, and further preferably 10 to 100 parts by mass based on 100 parts by mass of the charged monomer.

[First Solvent]

The first solvent has a function of reducing the surface tension of the ink composition for organic light-emitting device.

The first solvent has a surface tension of 25 mN/m or less, preferably less than 23 mN/m, and more preferably 15 mN/m or more and less than 23 mN/m. In this specification, the value of “surface tension” is the value measured by a plate method.

The first solvent may be any solvent having a surface tension of 25 mN/m or less and can be, for example, a fluorine-containing aromatic solvent, such as trifluoromethoxybenzene (TFMB); an alkane solvent, such as pentane, hexane, octane, nonane, decane, undecane, dodecane, or cyclohexane; an ether solvent, such as dibutyl ether, dioxane, or ethylene glycol dimethyl ether; or a ketone solvent, such as methyl ethyl ketone (MEK), methyl isobutyl ketone (MIBK), or diisobutyl ketone (DIBK).

Among these solvents, preferred are the fluorine-containing aromatic solvent, the alkane solvent, and the ketone solvent, and more preferred are trifluoromethoxybenzene (TFMB), decane, and methyl isobutyl ketone (MIBK).

The above-mentioned first solvents may be used alone or in combination of two or more thereof.

The content of the first solvent is preferably 5 to 99 mass % and more preferably 10 to 90 mass % based on the total amount of the ink composition for organic light-emitting device. A first solvent content of 5 mass % or more can provide suitable wettability of the ink composition for organic light-emitting device and is therefore preferred. In contrast, a first solvent content of 99 mass % or less can suppress or prevent precipitation of the first organic light-emitting device material and is therefore preferred.

[Aromatic Solvent]

The aromatic solvent has a function of dissolving the first organic light-emitting device material contained in the ink composition for organic light-emitting device.

The aromatic solvent can be any solvent including an aromatic group, and a known aromatic solvent can be used without particular limitation.

Specifically, examples of the aromatic solvent include monocyclic aromatic solvents, such as toluene, xylene, ethylbenzene, cumene, pentylbenzene (amylbenzene), hexylbenzene, cyclohexylbenzene, dodecylbenzene, mesitylene, diphenylmethane, dimethoxybenzene, phenetole, methoxytoluene, anisole, methylanisole, and dimethylanisole; condensed cyclic aromatic solvents, such as cyclohexylbenzene, tetralin, naphthalene, and methylnaphthalene; aromatic ether solvents, such as methylphenyl ether, ethylphenyl ether, propylphenyl ether, and butylphenyl ether; and aromatic ester solvents, such as phenyl acetate, phenyl propionate, ethyl benzoate, propyl benzoate, and butyl benzoate.

Among these solvents, preferred are the monocyclic aromatic solvent and the condensed cyclic aromatic solvent, and more preferred are amylbenzene and tetralin.

The above-mentioned aromatic solvents may be used alone or in combination of two or more thereof.

A solvent having a surface tension of 25 mN/m or less, such as trifluoromethoxybenzene, corresponds to the first solvent even if the solvent includes an aromatic group and is not included in the aromatic solvent. That is, the aromatic solvent has a surface tension higher than 25 mN/m.

The upper limit of the surface tension of the aromatic solvent is not particularly limited, but is preferably less than 36 mN/m, more preferably less than 35 mN/m, further preferably 32 mN/m or less, particularly preferably 30 mN/m or less, and most preferably 28 mN/m or less. An aromatic solvent having a surface tension of less than 36 mN/m increases the wettability of the ink composition for organic light-emitting device and is therefore preferred.

Herein, the surface tension value of a solvent can be controlled by appropriately modifying the structural formula. Specifically, introduction of a substituent into a solvent tends to reduce the surface tension. More specifically, introduction of a fluorine atom, a fluorine-containing functional group, alkyl, alkyl ether, or cycloalkyl as a substituent tends to reduce the surface tension in this order.

The content of the aromatic solvent is preferably 10 to 90 mass % and more preferably 30 to 70 mass % based on the total amount of the ink composition for organic light-emitting device. An aromatic solvent content of 10 mass % or more can suppress or prevent precipitation of the first organic light-emitting device material and is therefore preferred. In contrast, an aromatic solvent content of 90 mass % or less can provide suitable wettability of the ink composition for organic light-emitting device and is therefore preferred.

[First Solvent and Aromatic Solvent]

In one embodiment, it is preferred to adjust the types and the mixing ratio of the first solvent and the aromatic solvent from the viewpoint of ensuring the wettability of the ink composition for organic light-emitting device.

Specifically, the solvent surface energy A represented by Expression (1) is preferably less than 30, more preferably less than 29, further preferably less than 28, and particularly preferably less than 26.

$$\begin{matrix}[ Math . 2 ] & \\ A = ( {E}_{1} \times \frac{{W}_{1}}{{W}_{1} + {W}_{2}} ) + ( {E}_{2} \times \frac{{W}_{2}}{{W}_{1} + {W}_{2}} ) & ( 1 )\end{matrix}$$

In the expression, E₁ represents the surface tension of the first solvent, and W₁ represents the mass of the first solvent. E₂ represents the surface tension of the aromatic solvent, and W₂ represents the mass of the aromatic solvent.

When two or more first solvents and/or aromatic solvents are contained, the solvent surface energy A represented by Expression (1) is calculated considering it. For example, when two first solvents are contained, the solvent surface energy A is calculated by the following expression, a modification of Expression (1).

$$[ Math . 3 ]$$

$$A = ( {E}_{1 - 1} \times \frac{{W}_{1 - 1}}{{W}_{1 - 1} + {W}_{1 - 2} + {W}_{2}} ) + ( {E}_{1 - 2} \times \frac{{W}_{1 - 2}}{{W}_{1 - 1} + {W}_{1 - 2} + {W}_{2}} ) + ( {E}_{2} \times \frac{{W}_{2}}{{W}_{1 - 1} + {W}_{1 - 2} + {W}_{2}} )$$

In the expression, E₁₋₁ and W₁₋₁ respectively represent the surface tension and the mass of one of the first solvents, and E₁₋₂ and W₁₋₂ respectively represent the surface tension and the mass of the other of the first solvents.

The solvent surface energy A is that determined by considering the surface tension as the solvents contained in the ink composition for organic light-emitting device, and a smaller solvent surface energy A is more excellent in wettability.

<Method of Producing Ink Composition for Organic Light-Emitting Device>

In one embodiment of the present invention, although the ink composition for organic light-emitting device may be produced by any method, examples of the method include (1) a method involving preparation of a solution or dispersion containing a leveling agent and solvents (a first solvent and an aromatic solvent) and then addition of a first organic light-emitting device material to the solution or dispersion, (2) a method involving preparation of a solution or dispersion containing a first organic light-emitting device material and solvents (a first solvent and an aromatic solvent) and then addition of a leveling agent to the solution or dispersion, and (3) a method involving preparation of a solution or dispersion containing a leveling agent and a solvent or solvents (a first solvent and/or an aromatic solvent) and a solution or dispersion containing a first organic light-emitting device material and a solvent or solvents (an aromatic solvent and/or a first solvent) and mixing of these solutions or dispersions.

In the case of preparing an ink composition for organic light-emitting device for ink-jet recording, a viscosity of 1 to 20 mPa is preferred for ensuring sufficient discharge properties.

In the case of preparing an ink for ink-jet recording, it is preferred to avoid, for example, nozzle clogging due to coarse particles. Specifically, for example, a method of removing coarse particles by centrifugation or filter filtration is usually performed in an appropriate step of ink preparation.

The first organic light-emitting device material, the leveling agent, the first solvent, the aromatic solvent, and so on used in preparation of an ink are preferably high-purity products not containing impurities and ion components. By doing so, nozzle clogging based on generation of deposition on the nozzle caused by continuous ink-jet recording can be prevented. In addition, performance, reliability, and so on of the organic light-emitting device can be obtained.

The ink-jet recording ink prepared above can be applied to a known and commonly used ink-jet recording type printer, for example, various on-demand type printers, such as piezoelectric type and thermal (bubble jet) type.

<Organic Semiconductor Device>

According to one embodiment of the present invention, an organic semiconductor device is provided. The organic semiconductor device includes a second layer containing a second organic semiconductor device material and includes a first layer containing a first organic semiconductor device material and a leveling agent and disposed right above the second layer. The second layer has a surface energy of 28 mN/m or less. The leveling agent is a polymer at least containing a siloxane monomer as a monomer unit.

An organic light-emitting device will now be described in detail as an example of the organic semiconductor device. Those skilled in the art can prepare desired organic field-effect transistor and organic solar cell by referring to the description about the organic light-emitting device and considering common technical knowledge at the time of filing. It is understood that the resulting organic field-effect transistor and organic solar cell also have the advantageous effects of the present invention.

In one embodiment, the organic light-emitting device at least includes an anode, a light emitting layer, and a cathode. The organic light-emitting device may further include at least one additional layer, such as a hole injection layer, a hole transport layer, an electron transport layer, and an electron injection layer and may include a known component such as a sealing member.

[Second Layer]

The second layer has a surface energy of 28 mN/m or less, preferably 18 to 25 mN/m, and more preferably 18 to 23 mN/m.

Although the second layer is not particularly limited as long as the surface energy is 28 mN/m or less, it is usually a layer formed by a wet film-forming method. The second layer is formed by, for example, a method involving application and drying of an ink composition for organic light-emitting device (hereinafter, may be referred to as “second layer-forming ink composition”).

(Second Layer-Forming Ink Composition)

The second layer-forming ink composition usually includes a second organic light-emitting device material, a leveling agent (hereinafter, may be referred to as “second layer-forming leveling agent”), and a second solvent.

Second Organic Light-Emitting Device Material

The second layer allows formation of the first layer right thereabove by a wet film-forming method and is therefore a hole injection layer, a hole transport layer, a light emitting layer, an electron transport layer, or an electron injection layer, preferably a hole injection layer or a hole transport layer. Accordingly, the second organic light-emitting device material is preferably a hole injection material used for the hole injection layer or a hole transport material used for the hole transport layer.

Hole Injection Material

The hole injection material has a function of incorporating holes from the anode in the hole injection layer. On this occasion, the holes incorporated by the hole injection material are transported to the hole transport layer or the light emitting layer.

The hole injection material is not particularly limited, and examples thereof include phthalocyanine compounds, such as copper phthalocyanine; triphenylamine derivatives, such as 4,4′,4′″-tris[phenyl(m-tolyl)amino]triphenylamine; cyano compounds, such as 1,4,5,8,9,12-hexaazatriphenylene hexacarbonitrile and 2,3,5,6-tetrafluoro-7,7,8,8-tetracyano-quinodimethane; oxides, such as vanadium oxide and molybdenum oxide; amorphous carbon; and polymers, such as polyaniline (emeraldine), poly(3,4-ethylenedioxythiophene)-poly(styrenesulfonic acid) (PEDOT-PSS), and polypyrrole. Among these materials, the hole injection material is preferably a polymer and more preferably PEDOT-PSS.

The above-mentioned hole injection materials may be used alone or in combination of two or more thereof.

Hole Transport Material

The hole transport material can be that described above, and the description thereof is omitted.

Second Layer-Forming Leveling Agent

The second layer may contain a leveling agent.

Although the leveling agent is not particularly limited, it may be a polymer at least containing the above-mentioned siloxane monomer as a monomer unit or another leveling agent.

The leveling agent other than the polymer is not particularly limited, and examples thereof include silicone compounds, such as dimethyl silicone, methyl silicone, phenyl silicone, methylphenyl silicone, alkyl-modified silicone, alkoxy-modified silicone, aralkyl-modified silicone, and polyether-modified silicone; and fluorine compounds, such as polytetrafluoroethylene, polyvinylidene fluoride, fluoroalkyl methacrylate, perfluoropolyether, and perfluoroalkylethylene oxide.

These leveling agents may be used alone or in combination of two or more thereof.

Second Solvent

The second solvent is not particularly limited and can be an appropriate known solvent according to the layer to be formed. Specifically, the second solvent is, for example, an aromatic solvent, an alkane solvent, an ether solvent, an alcohol solvent, an ester solvent, an amide solvent, or another solvent.

Examples of the aromatic solvent include monocyclic aromatic solvents, such as toluene, xylene, ethylbenzene, cumene, pentylbenzene, hexylbenzene, cyclohexylbenzene, dodecylbenzene, mesitylene, diphenylmethane, dimethoxybenzene, phenetole, methoxytoluene, anisole, methylanisole, and dimethylanisole; condensed cyclic aromatic solvents, such as cyclohexylbenzene, tetralin, naphthalene, and methylnaphthalene; aromatic ether solvents, such as methylphenyl ether, ethylphenyl ether, propylphenyl ether, and butylphenyl ether; and aromatic ester solvents, such as phenyl acetate, phenyl propionate, ethyl benzoate, propyl benzoate, and butyl benzoate.

Examples of the alkane solvent include pentane, hexane, octane, and cyclohexane.

Examples of the ether solvent include dioxane, ethylene glycol dimethyl ether, ethylene glycol diethyl ether, ethylene glycol monobutyl ether, propylene glycol-1-monomethyl ether acetate, and tetrahydrofuran.

Examples of the alcohol solvent include methanol, ethanol, and isopropyl alcohol.

Examples of the ester solvent include ethyl acetate, butyl acetate, ethyl lactate, and butyl lactate.

Examples of the amide solvent include N,N-dimethylformamide, N,N-dimethylacetamide, and 2-pyrrolidone.

Other solvents are, for example, water, dimethyl sulfoxide, acetone, chloroform, and methylene chloride.

Among these solvents, the solvent preferably contains an aromatic solvent, more preferably contains at least one selected from the group consisting of condensed cyclic aromatic solvents, aromatic ether solvents, and aromatic ester solvents, and further preferably the solvent is a condensed cyclic aromatic solvent and/or an aromatic ether solvent.

The above-mentioned solvents may be used alone or in combination of two or more thereof.

The second layer-forming ink composition may have the same composition as that of the ink composition for organic light-emitting device according to the present invention.

(Method of Forming Second Layer)

The method of forming the second layer is not particularly limited, and examples of the method include a method involving application and drying of the second layer-forming ink composition. On this occasion, the application, the conditions for drying, and so on are not particularly limited, and any known technique can be appropriately employed.

(Structure of Second Layer)

The second layer contains a second organic light-emitting device material.

The second layer preferably further contains a second layer-forming leveling agent. As a result, the second layer becomes a layer having excellent flatness and can have a low surface energy (28 mN/m or less).

[First Layer]

The first layer is disposed right above the second layer.

Since the second layer is preferably a hole injection layer or a hole transport layer, the first layer is preferably a hole transport layer or a light emitting layer.

The first layer is formed on the second layer having a low surface energy and is accordingly formed from the ink composition for organic light-emitting device according to the present invention. Therefore, the first layer contains an organic light-emitting device material and a leveling agent. On this occasion, the leveling agent is a polymer at least containing a siloxane monomer as a monomer unit.

Consequently, a film can be suitably formed even on a low surface energy layer (second layer).

The method of forming the first layer is not particularly limited, and a known technique can be appropriately employed.

As described above, the second layer is a low surface energy layer, and the first layer is a layer formed on the second layer by the ink composition for organic light-emitting device according to the present invention. The combination of the second layer and the first layer is preferably hole injection layer-hole transport layer, hole injection layer-light emitting layer, or hole transport layer-light emitting layer. In the case of an organic light-emitting device having a structure composed of hole injection layer-hole transport layer-light emitting layer, when the hole transport layer and the light emitting layer are formed from the ink composition for organic light-emitting device according to the present invention, the hole transport layer can be the first layer with respect to the hole injection layer (second layer) and simultaneously can be the second layer with respect to the light emitting layer (first layer).

The detailed structures of other layers constituting the first layer, the second layer, and the organic light-emitting device will now be described in detail.

[Anode]

Although the anode is not particularly limited, for example, a metal, such as gold (Au); copper iodide (CuI); indium tin oxide (ITO); tin oxide (SnO₂); or zinc oxide (ZnO) can be used. These materials may be used alone or in combination of two or more thereof.

Although the anode may have any thickness, the thickness is preferably 10 to 1000 nm and more preferably 10 to 200 nm.

The anode can be formed by a method, such as vapor deposition or sputtering. On this occasion, a pattern may be formed by photolithography or a method using a mask.

[Hole Injection Layer]

The hole injection layer is an optional component in the organic light-emitting device and has a function of incorporating holes from the anode. The holes incorporated from the anode are usually transported to the hole transport layer or the light emitting layer.

The materials that can be used for the hole injection layer are the same as those described above, and the description thereof is omitted.

Although the hole injection layer may have any thickness, the thickness is preferably 0.1 nm to 5 μm.

The hole injection layer may be a monolayer or may be a multilayer including at least two layers.

The hole injection layer can be formed by a wet film-forming method or a dry film-forming method.

When the hole injection layer is formed by a wet film-forming method, usually, the method includes a step of applying the ink composition for organic light-emitting device or second layer-forming ink composition according to the present invention and drying the resulting coated film. On this occasion, the method of the application is not particularly limited, and examples thereof include an ink-jet printing method, a relief printing method, a gravure printing method, a screen printing method, and a nozzle printing method.

When the hole injection layer is formed by a dry film-forming method, for example, a vacuum vapor deposition method or a spin coating method can be employed.

[Hole Transport Layer]

The hole transport layer is an optional component in the organic light-emitting device and has a function of efficiently transporting holes. The hole transport layer can also have a function of preventing transport of holes. The hole transport layer usually incorporates holes from the anode or the hole injection layer and transports the holes to the light emitting layer.

The materials that can be used for the hole transport layer are the same as those described above, and the description thereof is omitted.

Although the hole transport layer may have any thickness, the thickness is preferably 1 nm to 5 μm, more preferably 5 nm to 1 μm, and further preferably 10 to 500 nm.

The hole transport layer may be a monolayer or may be a multilayer including at least two layers.

The hole transport layer can be formed by a wet film-forming method or a dry film-forming method.

When the hole transport layer is formed by a wet film-forming method, usually, the method includes a step of applying the ink composition for organic light-emitting device or second layer-forming ink composition according to the present invention and drying the resulting coated film. On this occasion, the method of the application is not particularly limited, and examples thereof include an ink-jet printing method, a relief printing method, a gravure printing method, a screen printing method, and a nozzle printing method.

When the hole transport layer is formed by a dry film-forming method, for example, a vacuum vapor deposition method or a spin coating method can be employed.

[Light Emitting Layer]

The light emitting layer has a function of emitting light by using energy generated by recombination of holes and electrons injected into the light emitting layer.

The materials that can be used for the light emitting layer are the same as those described above, and the description thereof is omitted.

Although the light emitting layer may have any thickness, the thickness is preferably 2 to 100 nm and more preferably 2 to 20 nm.

The light emitting layer can be formed by a wet film-forming method or a dry film-forming method.

When the light emitting layer is formed by a wet film-forming method, usually, the method includes a step of applying the ink composition for organic light-emitting device or second layer-forming ink composition according to the present invention and drying the resulting coated film. On this occasion, the method of the application is not particularly limited, and examples thereof include an ink-jet printing method, a relief printing method, a gravure printing method, a screen printing method, and a nozzle printing method.

When the light emitting layer is formed by a dry film-forming method, for example, a vacuum vapor deposition method or a spin coating method can be employed.

[Electron Transport Layer]

The electron transport layer is an optional component in the organic light-emitting device and has a function of efficiently transporting electrons. The electron transport layer can also have a function of preventing transport of electrons. The electron transport layer usually incorporates electrons from the cathode or the electron injection layer and transports the electrons to the light emitting layer.

The material that can be used for the electron transport layer is not particularly limited, and examples thereof include metal complexes having a quinoline skeleton or a benzoquinoline skeleton, such as tris(8-quinolilato)aluminum (Alq), tris(4-methyl-8-quinolinolato)aluminum (Almq3), bis(10-hydroxybenzo[h]quinolinato)beryllium (BeBq2), and bis(2-methyl-8-quinolinolato)(p-phenylphenolato)aluminum (BAlq), bis(8-quinolinolato)zinc (Znq); metal complexes having a benzoxazoline skeleton, such as bis[2-(2′-hydroxyphenyl)benzoxazolate]zinc (Zn(BOX)2); metal complexes having a benzothiazoline skeleton, such as bis[2-(2′-hydroxyphenyl)benzothiazolate]zinc (Zn(BTZ)2); polyazole derivatives, such as 2-(4-biphenyl)-5-(4-tert-butylphenyl)-1,3,4-oxadiazole (PBD), 3-(4-biphenyl)-4-phenyl-5-(4-tert-butylphenyl)-1,2,4-triazole (TAZ), 1,3-bis[5-(p-tert-butylphenyl)-1,3,4-oxadiazol-2-yl]benzene (OXD-7), 9-[4-(5-phenyl-1,3,4-oxadiazol-2-yl)phenyl]carbazole (CO11), 2,2′,2″-(1,3,5-benzenetriyl)tris(1-phenyl-1H-benzoimidazole) (TPBI), and 2-[3-(dibenzothiophen-4-yl)phenyl]-1-phenyl-1H-benzoimidazole (mDBTBIm-II); benzoimidazole derivatives represented by the following chemical formula ET-1; quinoline derivatives; perylene derivatives; pyridine derivatives; pyrimidine derivatives; quinoxaline derivatives; diphenylquinone derivatives; and nitro substituted fluorene derivatives.

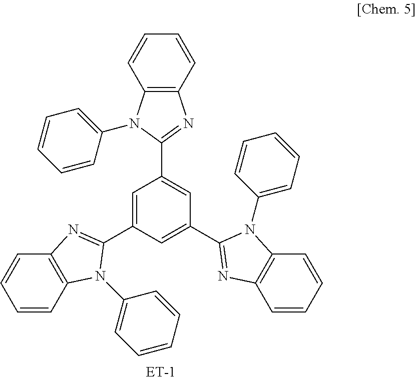 [SMILES: c1ccc(-n2c(-c3cc(-c4nc5ccccc5n4-c4ccccc4)cc(-c4nc5ccccc5n4-c4ccccc4)c3)nc3ccccc32)cc1]

The above-mentioned electron transport materials may be used alone or in combination of two or more thereof.

Although the electron transport layer may have any thickness, the thickness is preferably 5 nm to 5 μm and more preferably 5 to 200 nm.

The electron transport layer may be a monolayer or may be a multilayer including at least two layers.

The electron transport layer can be usually formed by, for example, a vacuum vapor deposition method, a spin coating method, a casting method, an ink-jet method, or an LB method.

[Electron Injection Layer]

The electron injection layer is an optional component in the organic light-emitting device and has a function of incorporating electrons from the cathode. The electrons incorporated from the cathode are usually transported to the electron transport layer or the light emitting layer.

The material that can be used for the electron injection layer is not particularly limited, and examples thereof include a buffer layer of a metal such as strontium and aluminum; a buffer layer of an alkali metal compound such as lithium fluoride; a buffer layer of an alkaline-earth metal compound such as magnesium fluoride; and a buffer layer of an oxide such as aluminum oxide. These materials may be used alone or in combination of two or more thereof.

Although the electron injection layer may have any thickness, the thickness is preferably 0.1 nm to 5 μm.

The electron injection layer may be a monolayer or may be a multilayer including at least two layers.

The electron injection layer can be usually formed by, for example, a vacuum vapor deposition method, a spin coating method, a casting method, an ink-jet method, or an LB method.

[Cathode]

The cathode is not particularly limited, and examples thereof include lithium, sodium, magnesium, aluminum, a sodium-potassium alloy, a magnesium/aluminum mixture, a magnesium/indium mixture, aluminum/aluminum oxide (Al₂O₃) mixture, and a rare earth metal. These materials may be used alone or in combination of two or more thereof.

The cathode can be usually formed by vapor deposition or sputtering.

Although the cathode may have any thickness, the thickness is preferably 10 to 1000 nm and more preferably 10 to 200 nm.

### EXAMPLES

The present invention will now be specifically described by EXAMPLES, but the present invention is not limited to the EXAMPLES. Note that “part(s)” in the EXAMPLES means “part(s) by mass” unless specifically defined otherwise.

### Example 1

A mixed liquid was prepared by mixing 0.005 parts of a leveling agent MCS-01 (polyether-modified silicone oil, random polymer) represented by the following formula, 50 parts of trifluoromethoxybenzene (TFMB, surface tension: 22 mN/M) as a first solvent, and 50 parts of tetralin (surface tension: 35 mN/M) as an aromatic solvent. The MCS-01 was synthesized by a reaction of methyl hydrogen silicone oil with an alkenyl compound in the presence of a platinum catalyst.

To the mixed liquid was added 0.01 parts of a hole transport material HTM-01 represented by the following formula (number of repeated units: 100, available from ADS Corporation), and the mixture was heated for dissolution. The mixture was cooled to room temperature and was filtered through a filter of 0.45 μm, MyShoriDisk (available from Tosoh Corporation), to remove foreign substances. An ink composition for organic light-emitting device was thus produced.

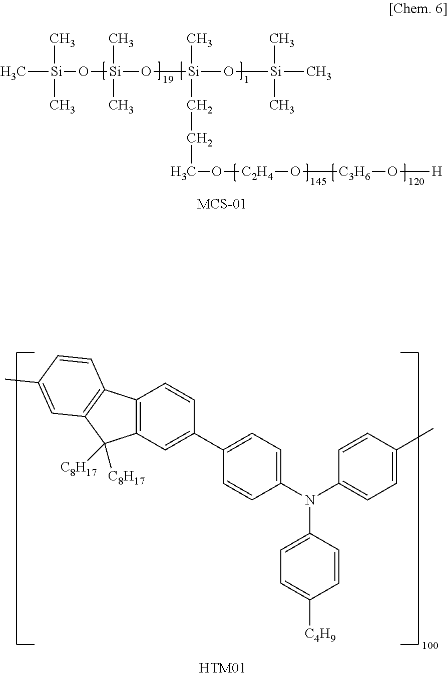

The solvent surface energy A represented by the following Expression (1) was 28.5.

$$\begin{matrix}[ Math . 4 ] & \\ A = ( {E}_{1} \times \frac{{W}_{1}}{{W}_{1} + {W}_{2}} ) + ( {E}_{2} \times \frac{{W}_{2}}{{W}_{1} + {W}_{2}} ) & ( 1 )\end{matrix}$$

The silicon content rate of the leveling agent was 4.1 mass %. On this occasion, the silicon content rate of the leveling agent was measured by the following method: The molar ratio between a polyether-modified moiety and a dimethylsiloxane moiety was determined by ¹H-NMR, and the mass % was calculated.

### Examples 2 to 10

Ink compositions for organic light-emitting device were produced as in EXAMPLE 1 except that the first solvent was changed to octane (surface tension: 21 mN/M), nonane (surface tension: 22 mN/M), decane (surface tension: 23 mN/M), undecane (surface tension: 24 mN/M), dodecane (surface tension: 25 mN/M), methyl ethyl ketone (MEK, surface tension: 24.6 mN/M), methyl isobutyl ketone (MIBK, surface tension: 23.6 mN/M), diisobutyl ketone (DIBK, surface tension: 23.9 mN/M), and dibutyl ether (surface tension: 22.4 mN/M), respectively.

The solvent surface energy A represented by Formula (1) was 28 when octane was used (EXAMPLE 2), 28.5 when nonane was used (EXAMPLE 3), 29 when decane was used (EXAMPLE 4), 29.5 when undecane was used (EXAMPLE 5), 30 when dodecane was used (EXAMPLE 6), 29.8 when methyl ethyl ketone was used (EXAMPLE 7), 29.3 when methyl isobutyl ketone was used (EXAMPLE 8), 29.5 when diisobutyl ketone was used (EXAMPLE 9), and 28.7 when dibutyl ether was used (EXAMPLE 10).

### Example 11

An ink composition for organic light-emitting device was produced as in EXAMPLE 1 except that the leveling agent was changed to a leveling agent MCS-02 (aralkyl-modified silicone oil, random polymer, containing aromatic group-containing monomer, represented by the following formula. The MCS-02 was synthesized as in EXAMPLE 1 except that the monomer was changed to another one.

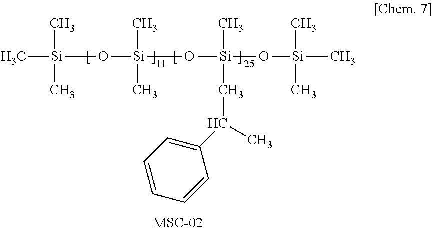

The solvent surface energy A represented by Expression (1) was 28.5.

The silicon content rate of the leveling agent measured as in EXAMPLE 1 was 19.3 mass %.

### Examples 12 and 13

Ink compositions for organic light-emitting device were produced as in EXAMPLE 11 except that the solvent was changed to decane (surface tension: 23 mN/M) and methyl isobutyl ketone (MIBK, surface tension: 23.6 mN/M), respectively.

The solvent surface energy A represented by Expression (1) was 29 when decane was used (EXAMPLE 12) and 29.3 when methyl isobutyl ketone was used (EXAMPLE 13).

### Example 14

An ink composition for organic light-emitting device was produced as in EXAMPLE 1 except that the leveling agent was changed to a leveling agent MCS-03 (aralkyl-modified silicone oil, random polymer, containing an aromatic group-containing monomer) represented by the following formula, synthesized as in MCS-01.

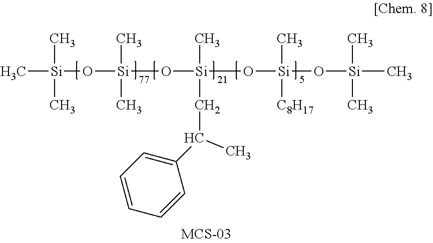

The solvent surface energy A represented by Expression (1) was 28.5.

The silicon content rate of the leveling agent measured as in EXAMPLE 1 was 21.1 mass %.

### Examples 15 and 16

Ink compositions for organic light-emitting device were produced as in EXAMPLE 14 except that the solvent was changed to decane (surface tension: 23 mN/M) and methyl isobutyl ketone (MIBK, surface tension: 23.6 mN/M), respectively.

The solvent surface energy A represented by Expression (1) was 29 when decane was used (EXAMPLE 15) and 29.3 when methyl isobutyl ketone was used (EXAMPLE 16).

### Example 17

An ink composition for organic light-emitting device was produced as in EXAMPLE 1 except that the leveling agent was changes to SP01 (block polymer, containing an aromatic group-containing monomer) represented by the following formula. The SP01 was synthesized using silicone macromer FM0711 (JNC Corporation) and styrene through living anionic polymerization by n-butyl lithium.

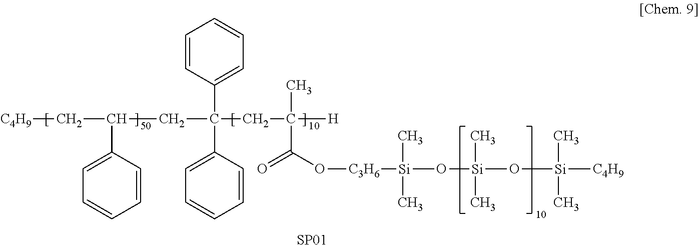

The solvent surface energy A represented by Expression (1) was 28.5.

The silicon content rate of the leveling agent measured as in EXAMPLE 1 was 20.0 mass %.

### Examples 18 to 20

Ink compositions for organic light-emitting device were produced as in EXAMPLE 17 except that the first solvent was changed to decane (surface tension: 23 mN/M), methyl isobutyl ketone (MIBK, surface tension: 23.6 mN/M), and dibutyl ether (surface tension: 22.4 mN/M), respectively.

The solvent surface energy A represented by Expression (1) was 29 when decane was used (EXAMPLE 18), 29.3 when methyl isobutyl ketone was used (EXAMPLE 19), and 28.7 when dibutyl ether was used (EXAMPLE 20).

### Example 21

An ink composition for organic light-emitting device was produced as in EXAMPLE 1 except that the leveling agent was changed to SP02 (block polymer, containing an aromatic group-containing monomer) represented by the following formula, synthesized as in SP01.

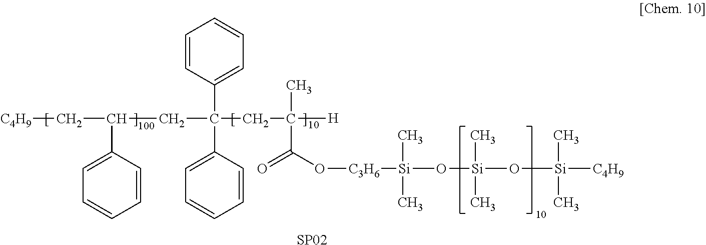

The solvent surface energy A represented by Expression (1) was 28.5.

The silicon content rate of the leveling agent measured as in EXAMPLE 1 was 14.9 mass %.

### Examples 22 to 24

Ink compositions for organic light-emitting device were produced as in EXAMPLE 21 except that the first solvent was changed to decane (surface tension: 23 mN/M), methyl isobutyl ketone (MIBK, surface tension: 23.6 mN/M), and dibutyl ether (surface tension: 22.4 mN/M), respectively.

The solvent surface energy A represented by Expression (1) was 29 when decane was used (EXAMPLE 22), 29.3 when methyl isobutyl ketone was used (EXAMPLE 23), and 28.7 when dibutyl ether was used (EXAMPLE 24).

### Example 25

An ink composition for organic light-emitting device was produced as in EXAMPLE 1 except that the leveling agent was changed to SP03 (random polymer, containing an aromatic group-containing monomer) represented by the following formula. The SP03 was synthesized using silicone macromer FM0711 (JNC Corporation) and styrene through polymerization by t-butyl peroxybenzoate.

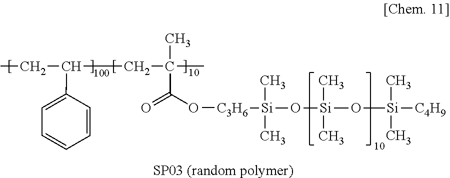

The solvent surface energy A represented by Expression (1) was 28.5.

The silicon content rate of the leveling agent measured as in EXAMPLE 1 was 14.9 mass %.

### Example 26

An ink composition for organic light-emitting device was produced as in EXAMPLE 1 except that the leveling agent was changed to SP04 (block polymer, containing an aromatic group-containing monomer) represented by the following formula. The SPO4 was synthesized as in SP03 in EXAMPLE 25 except that the monomer was changed.

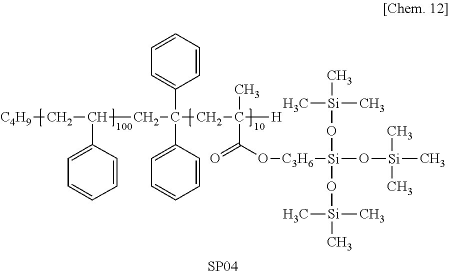

The solvent surface energy A represented by Expression (1) was 28.5.

The silicon content rate of the leveling agent measured as in EXAMPLE 1 was 15.1 mass %.

### Example 27

An ink composition for organic light-emitting device was produced as in EXAMPLE 1 except that the aromatic solvent was changed to amylbenzene (surface tension: 29 mN/M).

The solvent surface energy A represented by Expression (1) was 25.5.

### Examples 28 and 29

Ink compositions for organic light-emitting device were produced as in EXAMPLE 27 except that the first solvent was changed to undecane (surface tension: 24 mN/M) and diisobutyl ketone (DIBK, surface tension: 23.9 mN/M), respectively.

The solvent surface energy A represented by Expression (1) was 26.5 when undecane was used (EXAMPLE 28) and 26.5 when diisobutyl ketone was used (EXAMPLE 29).

### Examples 30 to 35

Ink compositions for organic light-emitting device were produced as in EXAMPLE 8 except that the aromatic solvent was changed to xylene (surface tension: 29 mN/M), mesitylene (surface tension: 28 mN/M), cyclohexylbenzene (surface tension: 34 mN/M), l-methylnaphthalene (surface tension: 39 mN/M), butylphenyl ether (surface tension: 31 mN/M), and ethyl benzoate (surface tension: 35 mN/M), respectively.

The solvent surface energy A represented by Expression (1) was 26.3 when xylene was used (EXAMPLE 30), 25.8 when mesitylene was used (EXAMPLE 31), 28.8 when cyclohexylbenzene was used (EXAMPLE 32), 31.3 when 1-methylnaphthalene was used (EXAMPLE 33), 27.3 when butylphenyl ether was used (EXAMPLE 34), and 29.3 when ethyl benzoate was used (EXAMPLE 35).

### Examples 36 to 42

Ink compositions for organic light-emitting device were produced as in EXAMPLE 19 except that the aromatic solvent was changed to amylbenzene (surface tension: 29 mN/M), xylene (surface tension: 29 mN/M), mesitylene (surface tension: 28 mN/M), cyclohexylbenzene (surface tension: 34 mN/M), 1-methylnaphthalene (surface tension: 39 mN/M), butylphenyl ether (surface tension: 31 mN/M), and ethyl benzoate (surface tension: 35 mN/M), respectively.

The solvent surface energy A represented by Expression (1) was 26.3 when amylbenzene was used (EXAMPLE 36), 26.3 when xylene was used (EXAMPLE 37), 25.8 when mesitylene was used (EXAMPLE 38), 28.8 when cyclohexylbenzene was used (EXAMPLE 39), 31.3 when 1-methylnaphthalene was used (EXAMPLE 40), 27.3 when butylphenyl ether was used (EXAMPLE 41), and 29.3 when ethyl benzoate was used (EXAMPLE 42).

### Example 43

An ink composition for organic light-emitting device was produced as in EXAMPLE 17 except that the hole transport material was changed to HTM02 (available from ADS Corporation) represented by the following formula.

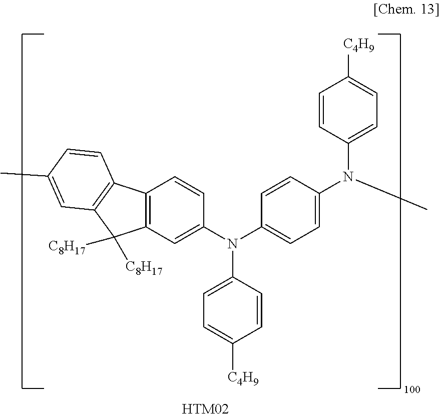

The solvent surface energy A represented by Expression (1) was 28.5.

### Examples 44 to 46

Ink compositions for organic light-emitting device were produced as in EXAMPLE 43 except that the first solvent was changed to decane (surface tension: 23 mN/M), methyl isobutyl ketone (MIBK, surface tension: 23.6 mN/M), and diisobutyl ketone (DIBK, surface tension: 23.9 mN/M), respectively.

The solvent surface energy A represented by Expression (1) was, 29 when decane was used (EXAMPLE 44), 29.3 when methyl isobutyl ketone was used (EXAMPLE 45), and 29.5 when diisobutyl ketone was used (EXAMPLE 46).

### Example 47

An ink composition for organic light-emitting device was produced as in EXAMPLE 17 except that the hole transport material was changed to HTM03 (available from Tokyo Chemical Industry Co., Ltd.) represented by the following formula.

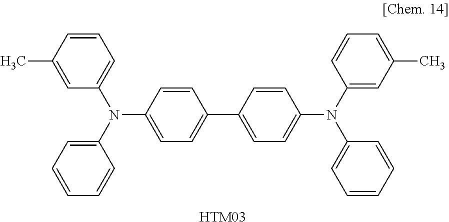

The solvent surface energy A represented by Expression (1) was 28.5.

### Examples 48 to 50

Ink compositions for organic light-emitting device were produced as in EXAMPLE 47 except that the first solvent was changed to decane (surface tension: 23 mN/M), methyl isobutyl ketone (MIBK, surface tension: 23.6 mN/M), and diisobutyl ketone (DIBK, surface tension: 23.9 mN/M), respectively.

The solvent surface energy A represented by Expression (1) was 29 when decane was used (EXAMPLE 48), 29.3 when methyl isobutyl ketone was used (EXAMPLE 49), and 29.5 when diisobutyl ketone was used (EXAMPLE 50).

### Comparative Example 1

A mixed liquid was prepared by mixing 0.005 parts of a leveling agent MCS-01 (polyether-modified silicone oil, random polymer) and 100 parts of an aromatic solvent tetralin (surface tension: 35 mN/M).

To the mixed liquid was added 0.01 parts of a hole transport material HTM-01 (available from ADS Corporation), and the mixture was heated for dissolution. The mixture was cooled to room temperature and was filtered through a filter of 0.45 μm, MyShoriDisk (available from Tosoh Corporation), to remove foreign substances. An ink composition for organic light-emitting device was thus produced.

### Comparative Example 2

A mixed liquid was prepared by mixing 0.005 parts of a leveling agent SP01 (block polymer, containing an aromatic group-containing monomer) and 100 parts of an aromatic solvent tetralin (surface tension: 35 mN/M).

To the mixed liquid was added 0.01 parts of a hole transport material HTM-01 (available from ADS Corporation), and the mixture was heated for dissolution. The mixture was cooled to room temperature and was filtered through a filter of 0.45 μm, MyShoriDisk (available from Tosoh Corporation), to remove foreign substances. An ink composition for organic light-emitting device was thus produced.

[Evaluation of Performance]

Performance was evaluated using the ink compositions for organic light-emitting device produced in EXAMPLES 1 to 50 and COMPARATIVE EXAMPLES 1 to 3.

(Evaluation of Contact Angle)

A low surface energy film was produced, and the contact angle of each of the ink compositions for organic light-emitting device on the low surface energy film was evaluated.

The low surface energy film was produced as follows: 1 part of poly(3,4-ethylenedioxythiophene)-poly(styrenesulfonic acid) (PEDOT-PSS) AI4083 (available from Cleviuos) and 0.5 parts of an aqueous dispersion solution containing 10% of Nafion (registered trademark) (copolymer of tetrafluoroethylene and perfluoro[2-(fluorosulfonylethoxy)propylvinyl ether]) (available from Sigma-Aldrich Co. LLC) were mixed. The resulting mixed liquid was spin-coated onto a glass substrate and was fired at 180° C. for 15 minutes to produce a low energy film.

One microliter of an ink composition for organic light-emitting device was dropped onto the low surface energy film with a syringe, and the contact angle was measured. The results were evaluated based on the following criteria.

x: a contact angle of larger than 30 degrees,

Δ: a contact angle of larger than 28 degrees and 30 degrees or less,

◯: a contact angle of larger than 26 degrees and 28 degrees or less, and

⊙: a contact angle of 26 degrees or less.

(Unevenness in Luminance)

Organic light-emitting devices were produced, and the unevenness in luminance of each of the resulting organic light-emitting devices was measured.

The organic light-emitting devices were each produced as follows.

That is, a mixed liquid was prepared by mixing 1 part of poly(3,4-ethylenedioxythiophene)-poly(styrenesulfonic acid) (PEDOT-PSS) AI4083 (available from Cleviuos) and 0.5 parts of an aqueous dispersion solution containing 10% of Nafion (registered trademark) (copolymer of tetrafluoroethylene and perfluoro[2-(fluorosulfonylethoxy)propylvinyl ether]) (available from Sigma-Aldrich Co. LLC).

Subsequently, a washed ITO substrate was irradiated with UV/O3, and the mixed liquid prepared above was spin-coated onto the substrate to form a 45-nm film, followed by heating in the air at 180° C. for 15 minutes to form a hole injection layer. An ink composition for organic light-emitting device was spin-coated onto the hole injection layer to form a 10-nm film, followed by drying in a nitrogen atmosphere at 200° C. for 30 minutes to form a hole transport layer. Subsequently, a 60-nm light emitting layer of tris(8-quinolinolato)aluminum (Alq), a 1.0-nm electron injection layer of lithium fluoride, and a 100-nm cathode of aluminum were sequentially formed under a vacuum condition of 5×10⁻³ Pa to produce an organic light-emitting device.

The thus-produced organic light-emitting device was connected to an external power source, and a current of 10 mA/cm² was flowed. The light emitted from the organic light-emitting device was measured with BM-9 (available from Topcon Corporation). On this occasion, the maximum luminance and the minimum luminance of the organic light-emitting device and the average in-plane luminance were measured, and the luminance variation rate was determined by the following expression.

$$\begin{matrix}[ Math . 5 ] & \\ Luminance variation rate ( \% ) = \frac{Maximum luminance - Minimum luminance}{Average in \text{-} plane luminance} \times 100 & \end{matrix}$$

The unevenness in luminance was evaluated according to the following criteria.

x: a luminance variation rate of higher than 70%,

Δ: a luminance variation rate of higher than 50% and 70% or less

◯: a luminance variation rate of higher than 30% and 50% or less

⊙: a luminance variation rate of higher than 20% and 30% or less, and

⊙⊙: a luminance variation rate of 20% or less.

The results are shown in Tables 1 to 5.

TABLE 1

| | First organic | Leveling agent | | | | | | | | | |
|---|---|---|---|---|---|---|---|---|---|---|---|
| | light- | Aromatic | | Silicon | First solvent | | Aromatic solvent | | | | |
| | emitting | group- | | content | | Surface | | Surface | | Evaluation results | |
| | device | containing | Polymerization | rate | | tension | | tension | Expression | Contact | Luminance |
| | material | monomer | form | (mass %) | Type* | (mN/m) | Type | (mN/m) | (1) | angle | unevenness |
| Example 1 | HTM01 | Absence | Random | 4.1 | TFMB | 22 | Tetralin | 35 | 28.5 | ◯ | Δ |
| Example 2 | HTM01 | Absence | Random | 4.1 | Octane | 21 | Tetralin | 35 | 28 | ◯ | Δ |
| Example 3 | HTM01 | Absence | Random | 4.1 | Nonane | 22 | Tetralin | 35 | 28.5 | ◯ | Δ |
| Example 4 | HTM01 | Absence | Random | 4.1 | Decane | 23 | Tetralin | 35 | 29 | Δ | Δ |
| Example 5 | HTM01 | Absence | Random | 4.1 | Undecane | 24 | Tetralin | 35 | 29.5 | Δ | Δ |
| Example 6 | HTM01 | Absence | Random | 4.1 | Dodecane | 25 | Tetralin | 35 | 30 | Δ | Δ |
| Example 7 | HTM01 | Absence | Random | 4.1 | MEK | 24.6 | Tetralin | 35 | 29.8 | Δ | Δ |
| Example 8 | HTM01 | Absence | Random | 4.1 | MIBK | 23.6 | Tetralin | 35 | 29.3 | Δ | Δ |
| Example 9 | HTM01 | Absence | Random | 4.1 | DIBK | 23.9 | Tetralin | 35 | 29.5 | Δ | Δ |
| Example 10 | HTM01 | Absence | Random | 4.1 | Dibutyl ether | 22.4 | Tetralin | 35 | 28.7 | ◯ | Δ |

*TFMB trifluoromethoxybenzene, MEK: methyl ethyl ketone, MIBK: methyl isobutyl ketone, DIBK: diisobutyl ketone

As obvious from the results of Table 1, it is demonstrated that in EXAMPLES 1 to 10, the contact angles are low, and each of the ink compositions for organic light-emitting device can be suitably applied even onto a low surface energy film.

It is also demonstrated that the organic light-emitting devices formed from the ink compositions for organic light-emitting device of EXAMPLES 1 to 10 have little unevenness in luminance.

Herein, it is demonstrated by comparison of EXAMPLES 1 to 3 and 10 with EXAMPLES 4 to 9 that when the surface tension of the first solvent is less than 23 or when the solvent surface energy A represented by Expression (1) is less than 29, as in EXAMPLES 1 to 3 and 10, higher performance of reducing the contact angle of the ink composition for organic light-emitting device is provided.

TABLE 2

| | First organic | Leveling agent | | | | | | | | | |
|---|---|---|---|---|---|---|---|---|---|---|---|
| | light- | Aromatic | | Silicon | First solvent | | Aromatic solvent | | | | |
| | emitting | group- | | content | | Surface | | Surface | | Evaluation results | |
| | device | containing | Polymerization | rate | | tension | | tension | Expression | Contact | Luminance |
| | material | monomer | form | (mass %) | Type | (mN/m) | Type | (mN/m) | (1) | angle | unevenness |
| Example 1 | HTM01 | Absence | Random | 4.1 | TFMB | 22 | Tetralin | 35 | 28.5 | ◯ | Δ |
| Example 4 | HTM01 | Absence | Random | 4.1 | Decane | 23 | Tetralin | 35 | 29 | Δ | Δ |
| Example 8 | HTM01 | Absence | Random | 4.1 | MIBK | 23.6 | Tetralin | 35 | 29.3 | Δ | Δ |
| Example 10 | HTM01 | Absence | Random | 41 | Dibutyl ether | 22.4 | Tetralin | 35 | 28.7 | ◯ | Δ |
| Example 11 | HTM01 | Presence | Random | 19.3 | TFMB | 22 | Tetralin | 35 | 28.5 | ◯ | ◯ |
| Example 12 | HTM01 | Presence | Random | 19.3 | Decane | 23 | Tetralin | 35 | 29 | ◯ | ◯ |
| Example 13 | HTM01 | Presence | Random | 19.3 | MIBK | 23.6 | Tetralin | 35 | 29.3 | ◯ | ◯ |
| Example 14 | HTM01 | Presence | Random | 21.1 | TFMB | 22 | Tetralin | 35 | 28.5 | ◯ | ◯ |
| Example 15 | HTM01 | Presence | Random | 21.1 | Decane | 23 | Tetralin | 35 | 29 | ◯ | ◯ |
| Example 16 | HTM01 | Presence | Random | 21.1 | MIBK | 23.6 | Tetralin | 35 | 29.3 | ◯ | ◯ |
| Example 17 | HTM01 | Presence | Block | 20.0 | TFMB | 22 | Tetralin | 35 | 28.5 | ⊙ | ⊙⊙ |
| Example 18 | HTM01 | Presence | Block | 20.0 | Decane | 23 | Tetralin | 35 | 29 | ⊙ | ⊙⊙ |
| Example 19 | HTM01 | Presence | Block | 20.0 | MIBK | 23.6 | Tetralin | 35 | 29.3 | ⊙ | ⊙⊙ |
| Example 20 | HTM01 | Presence | Block | 20.0 | Dibutyl ether | 22.4 | Tetralin | 35 | 28.7 | ⊙ | ⊙⊙ |
| Example 21 | HTM01 | Presence | Block | 14.9 | TFMB | 22 | Tetralin | 35 | 28.5 | ⊙ | ⊙ |
| Example 22 | HTM01 | Presence | Block | 14.9 | Decane | 23 | Tetralin | 35 | 29 | ⊙ | ⊙ |
| Example 23 | HTM01 | Presence | Block | 14.9 | MIBK | 23.6 | Tetralin | 35 | 29.3 | ◯ | ⊙ |
| Example 24 | HTM01 | Presence | Block | 14.9 | Dibutyl ether | 22.4 | Tetralin | 35 | 28.7 | ⊙ | ⊙ |
| Example 25 | HTM01 | Presence | Random | 14.9 | TFMB | 22 | Tetralin | 35 | 28.5 | ◯ | ◯ |
| Example 26 | HTM01 | Presence | Block | 15.1 | TFMB | 22 | Tetralin | 35 | 28.5 | ⊙ | ⊙ |

*TFMB: trifluoromethoxybenzene, MEK: methyl ethyl ketone, MIBK: methyl isobutyl ketone, DIBK: diisobutyl ketone

As obvious from the results of Table 2, it is demonstrated that in EXAMPLES 11 to 26, the contact angle values are low, and the ink compositions for organic light-emitting device can be suitably applied even on a low surface energy film. It is also demonstrated that the organic light-emitting devices formed from the ink compositions for organic light-emitting device of EXAMPLES 11 to 26 have little unevenness in luminance.

Herein, it is demonstrated by comparison of EXAMPLES 1, 4, 8, and 10 with EXAMPLES 11 to 16 and 25 that when the leveling agent includes an aromatic group-containing monomer as a monomer unit as in EXAMPLES 11 to 16, the unevenness in luminance is decreased.

In addition, it is demonstrated by comparison of EXAMPLES 11 to 16 and 25 with EXAMPLES 17 to 24 and 26 that when the leveling agent is a block copolymer as in EXAMPLES 17 to 24, the performance of reducing the contact angle and the unevenness in luminance is further enhanced.

It is demonstrated from EXAMPLES 17 to 24 and 26, in particular, EXAMPLES 17 to 20, that when the silicon content rate of the leveling agent is 20 mass % or more, the performance of reducing the unevenness in luminance is extremely high.

TABLE 3

| | First | | | | | | | | | | |
|---|---|---|---|---|---|---|---|---|---|---|---|
| | organic | Leveling agent | | | | | | | | | |
| | light- | Aromatic | | Silicon | First solvent | | Aromatic solvent | | | | |
| | emitting | group- | Poly- | content | | Surface | | Surface | Ex- | Evaluation results | |
| | device | containing | merization | rate | | tension | | tension | pression | Contact | Luminance |
| | material | monomer | form | (mass %) | Type | (mN/m) | Type | (mN/m) | (1) | angle | unevenness |
| Example 1 | HTM01 | Absence | Random | 4.1 | TFMB | 22 | Tetralin | 35 | 28.5 | ◯ | Δ |
| Example 5 | HTM01 | Absence | Random | 4.1 | Undecane | 24 | Tetralin | 35 | 29.5 | Δ | Δ |
| Example 8 | HTM01 | Absence | Random | 4.1 | MIBK | 23.6 | Tetralin | 35 | 29.3 | Δ | Δ |
| Example 9 | HTM01 | Absence | Random | 4.1 | DIBK | 23.9 | Tetralin | 35 | 29.5 | Δ | Δ |
| Example 19 | HTM01 | Presence | Block | 20.0 | MIBK | 23.6 | Tetralin | 35 | 29.3 | ⊙ | ⊙⊙ |
| Example 27 | HTM01 | Absence | Random | 4.1 | TFMB | 22 | Amylbenzene | 29 | 25.5 | ⊙ | Δ |
| Example 28 | HTM01 | Absence | Random | 4.1 | Undecane | 24 | Amylbenzene | 29 | 26.5 | ⊙ | Δ |
| Example 29 | HTM01 | Absence | Random | 4.1 | DIBK | 23.9 | Amylbenzene | 29 | 26.5 | ⊙ | Δ |
| Example 30 | HTM01 | Absence | Random | 4.1 | MIBK | 23.6 | Xylene | 29 | 26.3 | ◯ | Δ |
| Example 31 | HTM01 | Absence | Random | 4.1 | MIBK | 23.6 | Mesitylene | 28 | 25.8 | ⊙ | Δ |
| Example 32 | HTM01 | Absence | Random | 4.1 | MIBK | 23.6 | Cyclohexylbenzene | 34 | 28.8 | ◯ | Δ |
| Example 33 | HTM01 | Absence | Random | 4.1 | MIBK | 23.6 | 1-Methylnaphthalene | 39 | 31.3 | Δ | Δ |
| Example 34 | HTM01 | Absence | Random | 4.1 | MIBK | 23.6 | Butylphenyl ether | 31 | 27.3 | ◯ | Δ |
| Example 35 | HTM01 | Absence | Random | 4.1 | MIBK | 23.6 | Ethyl benzoate | 35 | 29.3 | Δ | Δ |
| Example 36 | HTM01 | Presence | Block | 20.0 | MIBK | 23.6 | Amylbenzene | 29 | 26.3 | ⊙ | ⊙⊙ |
| Example 37 | HTM01 | Presence | Block | 20.0 | MIBK | 23.6 | Xylene | 29 | 26.3 | ⊙ | ⊙⊙ |
| Example 38 | HTM01 | Presence | Block | 20.0 | MIBK | 23.6 | Mesitylene | 28 | 25.8 | ⊙ | ⊙⊙ |
| Example 39 | HTM01 | Presence | Block | 20.0 | MIBK | 23.6 | Cyclohexylbenzene | 34 | 28.8 | ⊙ | ⊙⊙ |
| Example 40 | HTM01 | Presence | Block | 20.0 | MIBK | 23.6 | 1-Methylnaphthalene | 39 | 31.3 | ◯ | ⊙⊙ |
| Example 41 | HTM01 | Presence | Block | 20.0 | MIBK | 23.6 | Butylphenyl ether | 31 | 27.3 | ⊙ | ⊙⊙ |
| Example 42 | HTM01 | Presence | Block | 20.0 | MIBK | 23.6 | Ethyl benzoate | 35 | 29.3 | ⊙ | ⊙⊙ |

*TFMB: trifluoromethoxybenzene, MIBK: methyl isobutyl ketone, DIBK: diisobutyl ketone

As obvious from the results of Table 3, it is demonstrated that in EXAMPLES 27 to 42, the contact angle values are low, and the ink compositions for organic light-emitting device can be suitably applied even onto a low surface energy film. It is also demonstrated that the organic light-emitting devices formed from the ink compositions for organic light-emitting device of EXAMPLES 27 to 42 have little unevenness in luminance.

Herein, it is demonstrated from comparison of EXAMPLES 1, 5, and 9 with EXAMPLES 27 to 29 that when the aromatic solvent has a surface tension of 30 mN/m or less or when the solvent surface energy A represented by Expression (1) is less than 28 as in EXAMPLES 27 to 29, the contact angle of the ink composition for organic light-emitting device is significantly high.

It is demonstrated by comparison of EXAMPLES 8, 33, and 35 with EXAMPLES 30 to 32 and 34 that when the aromatic solvent has a surface tension of 35 mN/m or less or the solvent surface energy A represented by Expression (1) is less than 29 as in EXAMPLES 30 to 32 and 34, the contact angle of the ink composition for organic light-emitting device is high. It is demonstrated that in particular, when the aromatic solvent has a surface tension of 28 mN/m or less or the solvent surface energy A represented by Expression (1) is less than 26 as in EXAMPLE 31, the contact angle of the ink composition for organic light-emitting device is significantly high.

It is demonstrated by comparison of EXAMPLE 40 with EXAMPLES 19, 36 to 39, 41, and 42 that when the aromatic solvent has a surface tension of less than 36 mN/m or the solvent surface energy A represented by Expression (1) is less than 30 as in EXAMPLES 19, 36 to 39, 41, and 42, the contact angle of the ink composition for organic light-emitting device is high.

TABLE 4

| | | Leveling agent | | | | | | | | | |
|---|---|---|---|---|---|---|---|---|---|---|---|
| | First organic | Aromatic | | | First solvent | | Aromatic solvent | | | | |
| | light-emitting | group- | | Silicon | | Surface | | Surface | | Evaluation results | |
| | device | containing | Polymerization | content rate | | tension | | tension | Expression | Contact | Luminance |
| | material | monomer | form | (mass %) | Type | (mN/m) | Type | (mN/m) | (1) | angle | unevenness |
| Example 17 | HTM01 | Presence | Block | 20.0 | TFMB | 22 | Tetralin | 35 | 28.5 | ⊙ | ⊙⊙ |
| Example 18 | HTM01 | Presence | Block | 20.0 | Decane | 23 | Tetralin | 35 | 29 | ⊙ | ⊙⊙ |
| Example 19 | HTM01 | Presence | Block | 20.0 | MIBK | 23.6 | Tetralin | 35 | 29.3 | ⊙ | ⊙⊙ |
| Example 43 | HTM02 | Presence | Block | 20.0 | TFMB | 22 | Tetralin | 35 | 28.5 | ⊙ | ⊙⊙ |
| Example 44 | HTM02 | Presence | Block | 20.0 | Decane | 23 | Tetralin | 35 | 29 | ⊙ | ⊙⊙ |
| Example 45 | HTM02 | Presence | Block | 20.0 | MIBK | 23.6 | Tetralin | 35 | 29.3 | ⊙ | ⊙⊙ |
| Example 46 | HTM02 | Presence | Block | 20.0 | DIBK | 23.9 | Tetralin | 35 | 29.5 | ⊙ | ⊙⊙ |
| Example 47 | HTM03 | Presence | Block | 20.0 | TFMB | 22 | Tetralin | 35 | 28.5 | ⊙ | ⊙⊙ |
| Example 48 | HTM03 | Presence | Block | 20.0 | Decane | 23 | Tetralin | 35 | 29 | ⊙ | ⊙⊙ |
| Example 49 | HTM03 | Presence | Block | 20.0 | MIBK | 23.6 | Tetralin | 35 | 29.3 | ⊙ | ⊙⊙ |
| Example 50 | HTM03 | Presence | Block | 20.0 | DIBK | 23.9 | Tetralin | 35 | 29.5 | ⊙ | ⊙⊙ |

*TFMB: trifluoromethoxybenzene, MIBK: methyl isobutyl ketone, DIBK: diisobutyl ketone

TABLE 5

| | | Leveling agent | | | | | | | | | |
|---|---|---|---|---|---|---|---|---|---|---|---|
| | First organic | Aromatic | | | First solvent | | Aromatic solvent | | | | |
| | light-emitting | group- | | Silicon | | Surface | | Surface | | Evaluation results | |
| | device | containing | Polymerization | content rate | | tension | | tension | Expression | Contact | Luminance |
| | material | monomer | form | (mass %) | Type | (mN/m) | Type | (mN/m) | (1) | angle | unevenness |
| Example 1 | HTM01 | Absence | Random | 4.1 | TFMB | 22 | Tetralin | 35 | 28.5 | ◯ | Δ |
| Example 17 | HTM01 | Presence | Block | 20.0 | TFMB | 22 | Tetralin | 35 | 28.5 | ⊙ | ⊙⊙ |
| Comparative | HTM01 | Absence | Random | 4.1 | — | — | Tetralin | 35 | 35 | X | X |
| Example 1 | | | | | | | | | | | |
| Comparative | HTM01 | Presence | Block | 20.0 | — | — | Tetralin | 35 | 35 | X | X |
| Example 2 | | | | | | | | | | | |

*TFMB: trifluormethoxybenzene

As obvious from the results of Table 4, it is demonstrated by comparison of EXAMPLES 17 to 19, EXAMPLES 43 to 46, and EXAMPLES 47 to 50 that all results are equivalent to one another.

As obvious from the results of Table 5, it is also demonstrated that the contact angles of COMPARATIVE EXAMPLES 1 and 2 are high and the unevenness in luminance is also large.

1. An ink composition for organic semiconductor device comprising a first organic semiconductor device material, a leveling agent, a first solvent, and an aromatic solvent, wherein
the leveling agent is a polymer at least containing a siloxane monomer as a monomer unit; and
the first solvent has a surface tension of 25 mN/m or less.

2. The ink composition for organic semiconductor device according to claim 1, wherein the leveling agent further contains an aromatic group-containing monomer as a monomer unit.

3. The ink composition for organic semiconductor device according to claim 1, wherein the leveling agent includes a block copolymer.

4. The ink composition for organic semiconductor device according to claim 1, wherein a silicon content rate of the leveling agent is 10 mass % or more.

5. The ink composition for organic semiconductor device according to claim 1, wherein the first solvent has a surface tension of less than 23 mN/m.

6. The ink composition for organic semiconductor device according to claim 1, wherein the aromatic solvent has a surface tension of less than 36 mN/m.

7. The ink composition for organic semiconductor device according to claim 1, wherein
a solvent surface energy A represented by Expression (1):
$$A = ( {E}_{1} \times \frac{{W}_{1}}{{W}_{1} + {W}_{2}} ) + ( {E}_{2} \times \frac{{W}_{2}}{{W}_{1} + {W}_{2}} ) \qquad ( 1 )$$
(where, E₁ represents the surface tension of the first solvent, W₁ represents the mass of the first solvent, E₂ represents the surface tension of the aromatic solvent, and W₂ represents the mass of the aromatic solvent)
is less than 30.

8. The ink composition for organic semiconductor device according to claim 1, wherein the first organic semiconductor device material is a hole transport material.

9. The ink composition for organic semiconductor device according to claim 1, wherein the organic semiconductor is an organic light-emitting device.

10. An organic semiconductor device comprising:
a second layer containing a second organic semiconductor device material; and
a first layer containing a first organic semiconductor device material and a leveling agent and disposed right above the second layer, wherein
the second layer has a surface energy of 28 mN/m or less; and
the leveling agent is a polymer at least containing a siloxane monomer as a monomer unit.

11. The organic semiconductor device according to claim 10, wherein the first organic semiconductor device material is a hole transport material.

12. The organic semiconductor device according to claim 11, wherein the organic semiconductor device is an organic light-emitting device.
